(19) United States
(12) Patent Application Publication
(10) Pub. No.: US 2024/0431206 A1
(43) Pub. Date: Dec. 26, 2024

(54) THERMALLY ACTIVATED DELAYED FLUORESCENT MATERIAL AND ELECTROLUMINESCENT DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xianwen MENG, Beijing (CN); Juncong LI, Beijing (CN); Junming ZHU, Beijing (CN); Lei CHEN, Beijing (CN)

(21) Appl. No.: 18/704,947

(22) PCT Filed: May 17, 2023
(86) PCT No.: PCT/CN2023/094722

§ 371 Date: Apr. 26, 2024

(30) Foreign Application Priority Data
Jun. 17, 2022 (CN) 202210692359.4

(51) Int. Cl. H10K 85/60; C07F 5/02; C09K 11/06; H10K 50/11; H10K 101/20

(52) U.S. Cl. CPC H10K 85/658; C07F 5/027; C09K 11/06; C09K 2211/1007; C09K 2211/1014; C09K 2211/1022; H10K 50/11; H10K 2101/20

(57) ABSTRACT

A thermally activated delayed fluorescent material and an electroluminescent device. The thermally activated delayed fluorescent material has a structure as shown in the following formula.

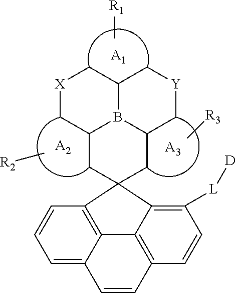

### CROSS-REFERENCE TO RELATED APPLICATIONS

This application is a U.S. National Phase Entry of International Application No. PCT/CN2023/094722, having an international filing date of May 17, 2023, which claims the priority of Chinese patent application filed in the Patent Office of China on Jun. 17, 2022, with the application number of 202210692359.4, and the invention title of “A thermally activated delayed fluorescence material and electroluminescent device”. The entire contents of above-identified applications are hereby incorporated into this application by reference.

### TECHNICAL FIELD

An embodiment of the application relates to, but is not limited to, the technical field of organic electroluminescent materials, and in particular relates to a thermally activated delayed fluorescence material and an electroluminescent device comprising the same with high efficiency.

### BACKGROUND

Charge transfer luminescent materials with thermally activated delayed fluorescence (TADF) properties have attracted great interest because of their wide applications in organic electroluminescent devices (OLED). TADF-type pure organic small molecule materials can make full use of singlet (¹CT)/triplet (³CT) excitons to emit light through effective reverse intersystem crossing (RISC), which greatly improves the luminescence efficiency of materials and promotes the development of organic electroluminescent devices. In TADF-type luminescent materials, a small singlet-triplet energy difference (ΔE_{ST}) is beneficial to promote the spin reversal transition from singlet to triplet, which is usually realized in molecules with charge transfer (CT) state.

Up to now, in addition to the commonly used donor-n-acceptor (D-n-A) TADF molecules with Through Bond Charge Transfer (TBCT), there are also TADF molecules with Through Space Charge Transfer (TSCT), which have attracted researchers' interest because of their extremely small ΔE_{ST}. In principle, TSCT occurs between D/A units stacked tightly in space. This phenomenon was first observed in the luminescent materials formed by bimolecular exciplexes. In this intermolecular TSCT system, the highest occupied molecular orbital (HOMO) and the lowest unoccupied molecular orbital (LUMO) are almost completely separated in the space state, which leads to a small energy level difference (ΔE_{ST}) between the singlet and triplet states of charge transfer. Later, it has been verified that there is intramolecular TSCT in monomolecular TADF luminescent materials, which is caused by the existence of π-π interaction due to the tight stacking of D and A units. Related studies have shown that the small energy gap between ¹CT and ³CT and the locally excited triplet state (³LE) close to ³CT in energy play a decisive role in fast RISC and efficient TADF properties.

### SUMMARY

The following is a summary of subject matters described herein in detail. This summary is not intended to limit the protection scope of claims. In order to further study the luminescence properties of TSCT-TADF materials, make the donor and acceptor units fully stacked, and at the same time, make them have a smaller ΔE_{ST} to promote the RISC process to achieve relatively high luminescence efficiency, the present disclosure designs a rigid coplanar conformation that arranges various donors and acceptors into various efficient TSCT-TADF emitters. The specific method is to chemically immobilize the acceptors with a rigid spirocyclic structure, use groups with different structural and electron donating strengths as donors, and align the various donors with the immobilized acceptors in a coplanar way, and at the same time, restrict them on the spirocyclic phenanthrene fluorene based linker to achieve the tight stacking, a series of TSCT-TADF small molecule luminescent materials with high luminescence performance are developed.

In the present disclosure, a TADF type organic luminescent material with space charge transfer properties was developed by fixing a boron containing fused ring with a spirocyclic phenanthrene fluorene group to construct receptor units with rigid structures, using carbazole, diphenylamine, triphenylamine, acridine, phenothiazine and derivatives thereof as donor units, and it was used as a guest luminescent material for organic electroluminescent devices, and shown good electroluminescent performance.

One embodiment of the present disclosure provides a compound of Formula 1:

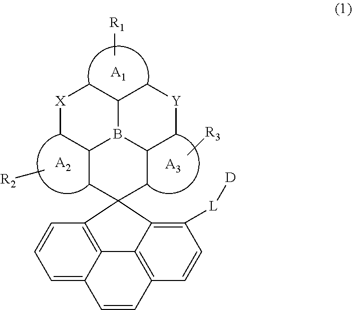

wherein, X and Y are each independently selected from one of O, S, Se, C═O, S(═O)₂, CR₄R₅, SiR₄R₅, NR₄, PR₄, P(═O)R₄, and BR₄.

A₁ to A₃ are each independently selected from substituted or unsubstituted C6-C18 aromatic ring, substituted or unsubstituted 5-18 membered heteroaromatic ring.

R₁ to R3 each independently represent 1 or more substituents, e.g., 1, 2, or 3 substituents, each independently selected from hydrogen (H), deuterium (D), halogen atom, cyano (CN), nitro (NO₂), hydroxy (OH), substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C6-C18 aryl, substituted or unsubstituted 5-18 membered heteroaryl, substituted or unsubstituted 5-18 membered heterocyclyl, or can be bonded with an adjacent group to form a 5-18 membered ring.

R₄ to R₅ are each independently selected from substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C6-C18 aryl, substituted or unsubstituted 5-18 membered heteroaryl, substituted or unsubstituted 5-18 membered heterocyclyl, or can be bonded with an adjacent group to form a 5-18 membered ring.

L is a linking group selected from a direct linking bond, an oxygen atom, substituted or unsubstituted C1-C6 alkylene, substituted or unsubstituted C1-C6 alkoxylene, substituted or unsubstituted C6-C18 arylene, substituted or unsubstituted C6-C18 aryloxylene, substituted or unsubstituted C1-C6 alkylene C6-C18 arylene, substituted or unsubstituted 5-18 membered heteroarylene, substituted or unsubstituted 5-18 membered heteroaryloxylene, substituted or unsubstituted C1-C6 alkylene 5-18 membered heteroarylene.

D is an electron-rich heterocyclyl group with hole transport ability.

In a second aspect, an embodiment of the present disclosure further provides a synthesis method of a compound of Formula 1 as described above, the synthesis method as shown in the following reaction equation 1 comprises:

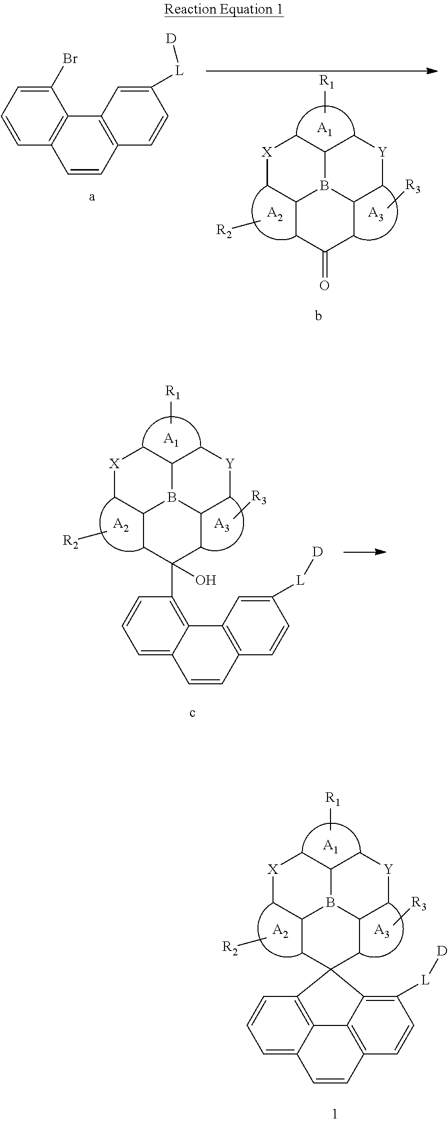

(1) reacting compound a with compound b to obtain compound c; and
(2) reacting the compound c to obtain a compound of Formula 1,
wherein, the definitions of each substituent are the same as the aforementioned definitions.

In a third aspect, another embodiment of the present disclosure provides use of the compound of the present disclosure described above for the preparation of an organic luminescent material. In one embodiment, the organic luminescent material is a TADF type organic luminescent material. In another embodiment, the organic luminescent material is a guest material or a sensitizing material of a luminescent layer.

In a fourth aspect, yet another embodiment of the present disclosure provides use of the compound of the present disclosure described above for the preparation of an organic electroluminescent device.

In a fifth aspect, yet another embodiment of the present disclosure provides an organic electroluminescent device comprising a luminescent layer comprising the compound of the present disclosure described above.

Other aspects may be comprehended upon reading and understanding the detailed description.

### DETAILED DESCRIPTION

In order to objectively evaluate the technical effect of the embodiments of the present disclosure, the technical solution provided by the present disclosure will be described in detail and exemplarily through the embodiments below. These embodiments are provided so that the present disclosure will be more comprehensive and complete and will fully convey the concepts of the exemplary embodiments to those skilled in the art. The features, structures, or characteristics described by these exemplary embodiments may be incorporated in one or more embodiments in any suitable manner so as to be capable of being implemented in various forms, and therefore should not be construed as being limited to the examples set forth herein. Apparently, the described embodiments are a part of the embodiments of the present disclosure, not all of the embodiments. All other embodiments obtained by those of ordinary skill in the art based on the embodiments provided by the present disclosure fall within the scope of protection of the present disclosure.

In the present disclosure, the description “each independently” as used should be understood broadly, which can mean that specific options expressed between the same symbols in different groups do not affect each other, or that specific options expressed between the same symbols in the same groups do not affect each other.

The non-localized substituent in the present disclosure refers to a substituent group connected by a single bond extending from the center of the ring system, which means that the substituent group can be connected to any possible position in the ring system.

In the present disclosure, “C1-C18”, “C2-C18”, “C3-C18”, “C6-C18” and the like preceding a group refer to the number of carbon atoms contained in the group. For example, the C7 aryl can be a tolyl with a carbon atom number of 7.

In the present disclosure, “5-18 membered”, “5-30 membered” and the like preceding a ring group refer to the number of ring atoms contained in the ring group. For example, a 5-membered ring refers to a ring with the number of ring atoms of 5.

In the present disclosure, when no specific definition is otherwise provided, “hetero” means that at least one heteroatom selected from B, N, O, S, Se, Si, P, etc. is included in a functional group.

In the present disclosure, “alkyl” may include straight or branched alkyl. Unless otherwise defined, alkyl may have 1 to 10 carbon atoms, and in the present disclosure, numerical ranges such as “1 to 10” refer to various integers in a given range. For example, “1 to 10 carbon atoms” refers to an alkyl that may contain 1, 2, 3, 4, 5, 6, 7, 8, 9 or 10 carbon atoms. The alkyl may also be a lower alkyl having 1 to 6 carbon atoms. In addition, the alkyl may be substituted or unsubstituted. Unsubstituted alkyl can be “saturated alkyl groups” without any double or triple bonds. Alternatively, the alkyl is selected from alkyl having 1 to 6 carbon atoms, including, but not limited to, methyl, ethyl, n-propyl, isopropyl, n-butyl, isobutyl, sec-butyl, tert-butyl, amyl and hexyl.

In the present disclosure, “alkylene” refers to a divalent group formed by further loss of one hydrogen atom from an alkyl.

In the present disclosure, “alkenyl” may include a straight or branched alkenyl containing at least one carbon-carbon double bond. Unless otherwise defined, the alkenyl may have 2 to 10 carbon atoms, and in the present disclosure, numerical ranges such as “2 to 10” refer to various integers in a given range. For example, “2 to 10 carbon atoms” refers to an alkenyl that may contain 2, 3, 4, 5, 6, 7, 8, 9 or 10 carbon atoms. The alkenyl may also be a lower alkenyl having 2 to 6 carbon atoms. In addition, the alkenyl group may be substituted or unsubstituted. Alternatively, the alkenyl is selected from alkenyl having 2-6 carbon atoms, including, but not limited to, vinyl, propen-1-yl, propen-2-yl, butenyl, pentenyl, hexenyl, and the like.

In the present disclosure, “alkynyl” may include a straight or branched alkynyl containing at least one carbon-carbon triple bond. Unless otherwise defined, the alkynyl may have 2 to 10 carbon atoms, and in the present disclosure, numerical ranges such as “2 to 10” refer to various integers in a given range. For example, “2 to 10 carbon atoms” refers to an alkynyl that may contain 2, 3, 4, 5, 6, 7, 8, 9 or 10 carbon atoms. The alkynyl may also be a lower alkynyl having 2 to 6 carbon atoms. In addition, the alkynyl may be substituted or unsubstituted. Alternatively, the alkynyl is selected from alkynyl having 2-6 carbon atoms, including, but not limited to, ethynyl, propynyl, butynyl, pentynyl, hexynyl, and the like.

In the present disclosure, cycloalkyl refers to a group derived from a saturated cyclic carbon chain structure. Unless otherwise defined, cycloalkyl may have 3 to 10 carbon atoms, and in the present disclosure, numerical ranges such as “3 to 10” refer to various integers in a given range. For example, “3 to 10 carbon atoms” refers to a cycloalkyl that can contain 3, 4, 5, 6, 7, 8, 9, 10 carbon atoms. The cycloalkyl may be substituted or unsubstituted. Alternatively, specific examples of cycloalkyl include but are not limited to cyclopentyl, cyclohexyl, and the like.

In the present disclosure, aryl refers to an optional functional group or substituent derived from an aromatic carbocyclic ring. The aryl may be a monocyclic aryl (e.g., phenyl) or a polycyclic aryl. In other words, the aryl may be a monocyclic aryl, a fused cyclic aryl, two or more monocyclic aryl conjugated by carbon-carbon bonds, monocyclic aryl and fused cyclic aryl conjugated by carbon-carbon bonds, two or more fused cyclic aryl conjugated by carbon-carbon bonds. That is to say, unless otherwise stated, two or more aromatic groups conjugated by carbon-carbon bonds may also be considered as aryl of the present disclosure. Among them, the fused cyclic aryl may include, for example, a bicyclic fused aryl (e.g., naphthyl), a tricyclic fused aryl (e.g., phenanthrenyl, fluorenyl, anthryl), and the like. The aryl does not contain heteroatoms such as B, N, O, S, P, Se and Si and the like. For example, in the present disclosure, biphenyl, triphenyl and the like are aryl. Examples of aryl may include, but are not limited to, phenyl, naphthyl, fluorenyl, anthryl, phenanthrene, biphenyl, triphenyl, tetraphenyl, pentaphenyl, benzo[9,10] phenanthryl, pyrenyl, benzofluoranthenyl, chrysenyl, etc. Unless otherwise defined, the “aryl” of the present disclosure may contain 6-30 carbon atoms. In some of examples, the number of carbon atoms in the aryl may be 6-25, in other examples, the number of carbon atoms in the aryl may be 6-18, and in other examples, the number of carbon atoms in the aryl may be 6-13. For example, in the present disclosure, the number of carbon atoms of the aryl may be 6, 10, 12, 13, 14, 15, 18, 20, 24, 25, 30, and of course, the number of carbon atoms may be other numbers, which will not be listed one by one here. In the present disclosure, the biphenyl may be understood as a phenyl substituted aryl or as an unsubstituted aryl.

In the present disclosure, heteroaryl is a monovalent aromatic ring containing at least one, e.g., 1, 2, 3, 4 or 5 heteroatoms in a ring, which may be at least one selected from B, O, N, P, Si, Se and S. The heteroaryl can be a monocyclic heteroaryl or a polycyclic heteroaryl. In other words, the heteroaryl can be a single aromatic ring system or a plurality of aromatic ring systems connected by conjugation, and any aromatic ring system is an aromatic monocyclic ring or an aromatic fused ring. For example, the heteroaryl may include thienyl, furyl, pyrrolyl, imidazolyl, thiazolyl, oxazolyl, oxadiazolyl, triazolyl, pyridyl, bipyridyl, pyrimidinyl, triazinyl, acridinyl, pyridazinyl, pyrazinyl, quinolinyl, quinazolinyl, quinoxalinyl, phenoxazinyl, phthalazinyl, pyridopyrimidinyl, pyridopyrazinyl, pyrazinopyrazinyl, isoquinoline, indolyl, carbazolyl, benzoxazolyl, benzimidazolyl, benzothiazolyl, benzotriazolyl, benzocarbazolyl, benzothiophenyl, dibenzothiophenyl, thienothiophenyl, benzofuranyl, phenanthrolinyl, isoxazolyl, thiadiazolyl, benzothiazolyl, phenothiazinyl, silfluorenyl, dibenzofuranyl and N-aryl carbazolyl (such as N-phenylcarbazolyl), N-heteroaryl carbazolyl (such as N-pyridyl carbazolyl), N-alkyl carbazolyl (such as N-methyl carbazolyl) and the like, but not limited thereto. Among them, thienyl, furyl, phenanthrolinyl, etc. are heteroaryl of single aromatic ring system type, and N-arylcarbazolyl and N-heteroaryl carbazolyl are heteroaryl of polycyclic system type connected by conjugation. Unless otherwise defined, the “heteroaryl” of this application may contain 5-30 ring atoms. In some of examples, the number of ring atoms in the heteroaryl may be 5-23, and in other examples the number of ring atoms in the heteroaryl may be 5-19. For example, the number of ring atoms can be 5, 6, 7, 10, 11, 12, 13, 18, 19, 20, 21, 22, 23, 25, or 30. Of course, the number of ring atoms can also be other numbers, which will not be listed one by one here. In the present disclosure, the substituted heteroaryl may be that one or more hydrogen atoms of the heteroaryl are substituted with groups such as deuterium atoms, halogen groups, cyano groups, aryl, heteroaryl, alkyl, cycloalkyl, etc. Specific examples of aryl-substituted heteroaryl include, but are not limited to, phenyl-substituted dibenzofuranyl, phenyl-substituted dibenzothienyl, N-phenylcarbazolyl, and the like. It should be understood that the number of carbon atoms of the substituted heteroaryl refers to the total number of carbon atoms of the heteroaryl and the substituent group on the heteroaryl.

In the present disclosure, heterocyclyl is a monovalent non-aromatic ring containing at least one, e.g., 1, 2, 3, 4 or 5 heteroatoms in a ring, which may be selected from at least one of B, O, N, P, Si, Se and S. Heterocyclyl can be monocyclic or polycyclic. For example, heterocyclyl may include, but are not limited to, dihydropyridyl, piperidinyl, tetrahydrothienyl, thioxidized tetrahydrothienyl, 4-piperidinonyl, pyrrolidinyl, 2-pyrrolidonyl, pyrrolinyl, tetrahydrofuranyl, bis-tetrahydrofuranyl, tetrahydropyranyl, bis-tetrahydropyranyl, tetrahydroquinolinyl, tetrahydroisoquinolinyl, decahydroquinolinyl, octahydroisoquinolinyl, azocinyl, phenanthridinyl, acridinyl, pyrimidinyl, imidazolidyl, imidazolinyl, pyrazolidinyl, pyrazolinyl, piperazinyl, indolinyl, isoindolinyl, quinuclidinyl, morpholinyl, oxazolidinyl, and the like.

In the present disclosure, alkoxy, alkylsulfanyl, aryloxy, arylsulfanyl, heteroaryloxy and heteroarylsulfanyl refer to a group formed by connecting one oxygen or sulfur atom at the end of the alkyl, aryl and heteroaryl described above.

In the present disclosure, alkylene, alkoxylene, arylene, aryloxylene, heteroarylene and heteroaryloxylene refer to divalent groups formed by the loss of one hydrogen atom from the alkyl, alkoxy, aryl, aryloxy, heteroaryl and heteroaryloxy.

In the present disclosure, the substituted or unsubstituted amine group refers to —NR′R″, where R′ and R″ are each independently selected from hydrogen, substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C6-C30 aryl, substituted or unsubstituted 5-30 membered heteroaryl, substituted or unsubstituted 5-30 membered heterocyclyl.

In the present disclosure, the halogen group may include fluorine, iodine, bromine, chlorine, and the like.

In the present disclosure, “ring” includes a ring of cycloalkyl, aryl, heteroaryl, heterocyclyl, and the like as defined above.

In the present disclosure, substituted alkyl, alkylene, alkenyl, alkynyl, cycloalkyl, alkoxy, alkoxylene, alkylsulfanyl, alkylamine group, aryl, aryloxy, arylsulfanyl, arylene, heteroaryl, heteroaryloxy, heteroarylene, heteroaryloxylene, heterocyclyl, and the like may be that one or more hydrogen atoms in these groups are substituted by groups such as deuterium, halogen group, cyano, nitro, amino, hydroxy, C6-C12 aryl, 5-12 membered heteroaryl, C1-C6 alkyl, C1-C6 alkoxy, C3-C6 cycloalkyl, and the like.

One embodiment of the present disclosure provides a compound of Formula 1:

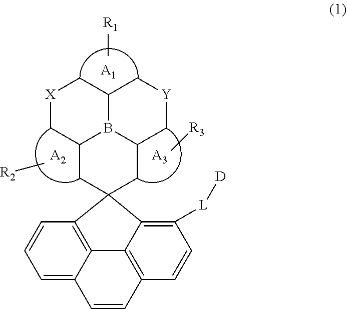

wherein, X and Y are each independently selected from one of O, S, Se, C═O, S(═O)₂, CR₄R₅, SiR₄R₅, NR₄, PR₄, P(═O)R₄, and BR₄.

A₁ to A₃ are each independently selected from substituted or unsubstituted C6-C18 aromatic ring, substituted or unsubstituted 5-18 membered heteroaromatic ring.

R₁ to R₃ each independently represent 1 or more substituents, e.g., 1, 2, or 3 substituents, each independently selected from hydrogen (H), deuterium (D), halogen atom, cyano (CN), nitro (NO₂), hydroxy (OH), substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C6-C18 aryl, substituted or unsubstituted 5-18 membered heteroaryl, substituted or unsubstituted 5-18 membered heterocyclyl, or can be bonded with an adjacent group to form a 5-18 membered ring.

R₄ to R₅ are each independently selected from substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C6-C18 aryl, substituted or unsubstituted 5-18 membered heteroaryl, substituted or unsubstituted 5-18 membered heterocyclyl, or can be bonded with an adjacent group to form a 5-18 membered ring.

L is a linking group selected from a direct linking bond, an oxygen atom, substituted or unsubstituted C1-C6 alkylene, substituted or unsubstituted C1-C6 alkoxylene, substituted or unsubstituted C6-C18 arylene, substituted or unsubstituted C6-C18 aryloxylene, substituted or unsubstituted C1-C6 alkylene C6-C18 arylene, substituted or unsubstituted 5-18 membered heteroarylene, substituted or unsubstituted 5-18 membered heteroaryloxylene, substituted or unsubstituted C1-C6 alkylene 5-18 membered heteroarylene.

D is an electron-rich heterocyclyl group with hole transport ability.

In one embodiment, the main type of D is of carbazole and its derivatives, fused carbazole and its derivatives, diphenylamine and its derivatives, aromatic heterocyclyl substituted diarylamine derivatives, acridine and its derivatives, phenoxazine and its derivatives, phenothiazine and its derivatives, and the like.

In one embodiment, D is selected from the following groups:

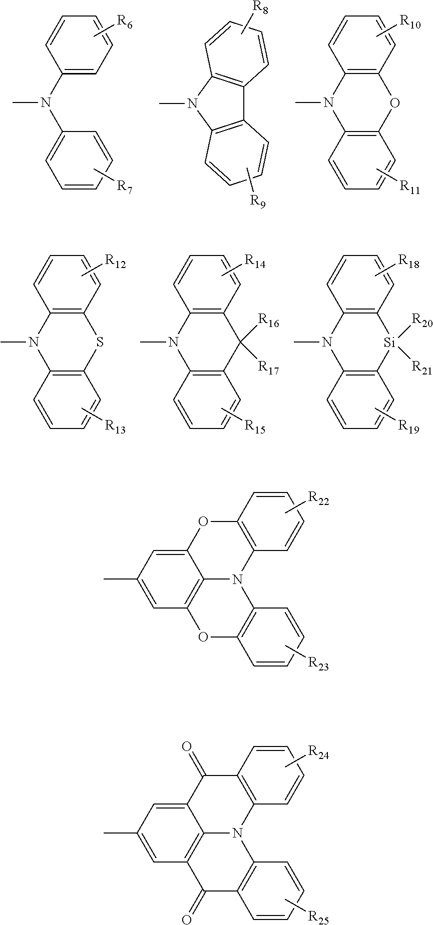

wherein, R₆ to R₁₅, R₁₈ to R₁₉, and R₂₂ to R₂₅ each independently represent 1 or more substituents, e.g., 1, 2, or 3 substituents, each independently selected from hydrogen, substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C1-C18 alkylsulfanyl, substituted or unsubstituted amine group, substituted or unsubstituted C6-C30 arylsulfanyl, substituted or unsubstituted C6-C30 aryloxy, substituted or unsubstituted C6-C30 aryl, substituted or unsubstituted 5-30 membered heteroaryl, or can be bonded with an adjacent group to form a 5-30 membered ring.
R₁₆ to R₁₇, and R₂₀ to R₂₁ are independently selected from hydrogen, substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C1-C18 alkylsulfanyl, substituted or unsubstituted C6-C30 arylsulfanyl, substituted or unsubstituted C6-C30 aryloxy, substituted or unsubstituted amine group, substituted or unsubstituted C6-C30 aryl, substituted or unsubstituted 5-30 membered heteroaryl, substituted or unsubstituted 5-30 membered heterocyclyl, or are bonded with an adjacent group to form a 5-30 membered ring.

In some embodiments, R₆ to R₁₅, R₁₈ to R₁₉, and R₂₂ to R₂₅ each independently represent 1 or 2 substituents, each independently selected from hydrogen, substituted or unsubstituted C1-C6 alkyl, or are bonded with an adjacent group to form a 5-20 membered ring.

In some embodiments, R₁₆ to R₁₇, and R₂₀ to R₂₁ are each independently selected from hydrogen, substituted or unsubstituted C1-C4 alkyl, substituted or unsubstituted C6-C10 aryl, or are bonded with an adjacent group to form a 5-20 membered ring.

In some embodiments, D is selected from the following groups:

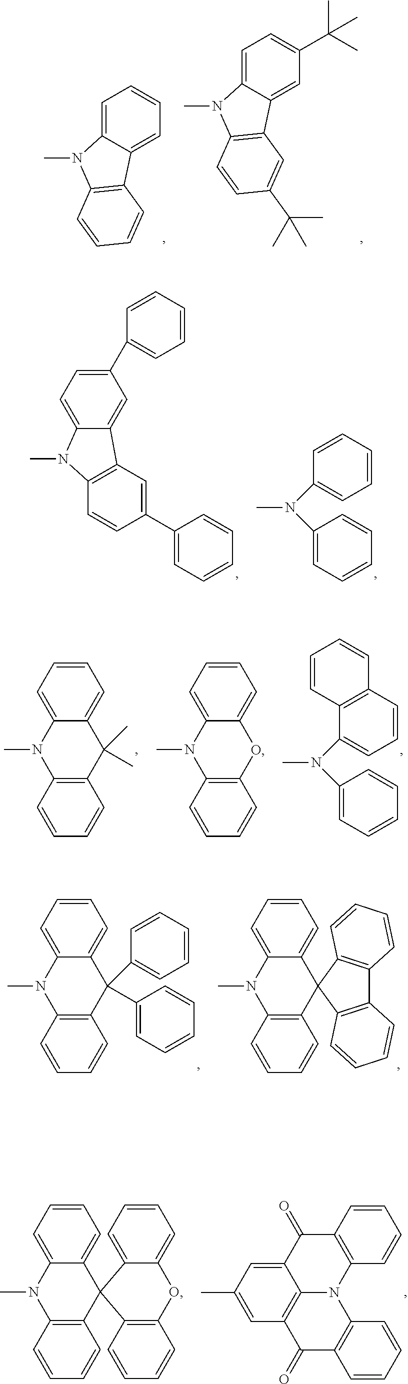

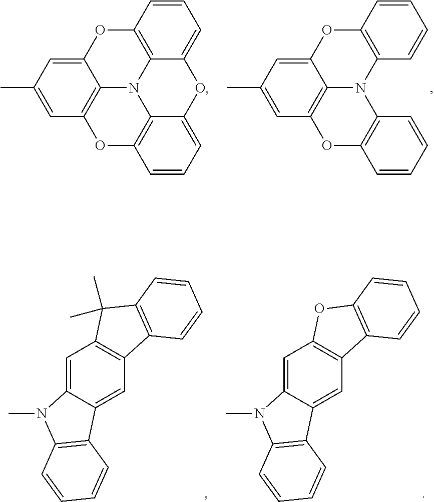

In some embodiments, L is selected from a direct linking bond, an oxygen atom, substituted or unsubstituted C1-C4 alkylene, substituted or unsubstituted C1-C4 alkoxylene, substituted or unsubstituted C6-C12 arylene, substituted or unsubstituted C6-C12 aryloxylene, substituted or unsubstituted C1-C4 alkylene C6-C12 arylene, substituted or unsubstituted 5-12 membered heteroarylene, substituted or unsubstituted 5-12 membered heteroaryloxylene, substituted or unsubstituted C1-C4 alkylene 5-12 membered heteroarylene.

In some embodiments, L is selected from a direct linking bond, an oxygen atom, phenylene, pyridylene, furylene, C1-C4 alkylene, C1-C4 alkylene phenylene, phenoxylene.

In some embodiments, X and Y are each independently selected from any one of O, S, Se, C═O, S(═O)₂, CR₄R₅, and BR₄.

In some embodiments, A₁ to A₃ are benzene rings.

In some embodiments, R₁ to R₃ each independently represent 1 to 2 substituents each independently selected from hydrogen, deuterium, cyano.

In some embodiments, R₄ to R₅ are each independently selected from hydrogen, deuterium, substituted or unsubstituted C1-C6 alkyl, substituted or unsubstituted C6-C10 aryl.

In some embodiments, the compound of Formula 1 is selected from the following compounds:

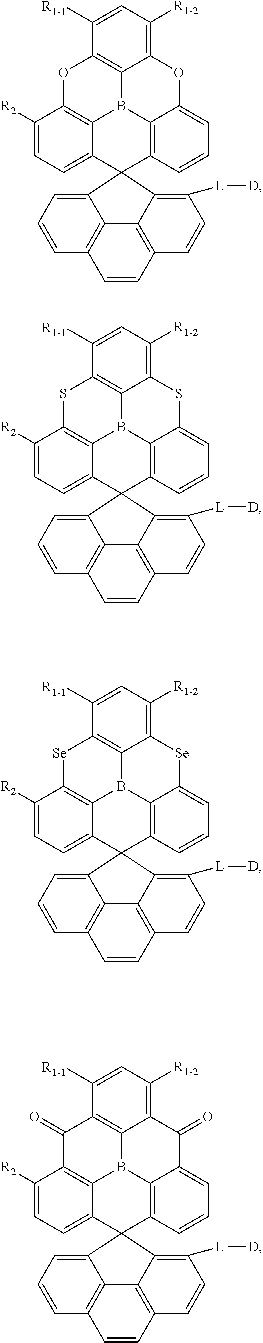

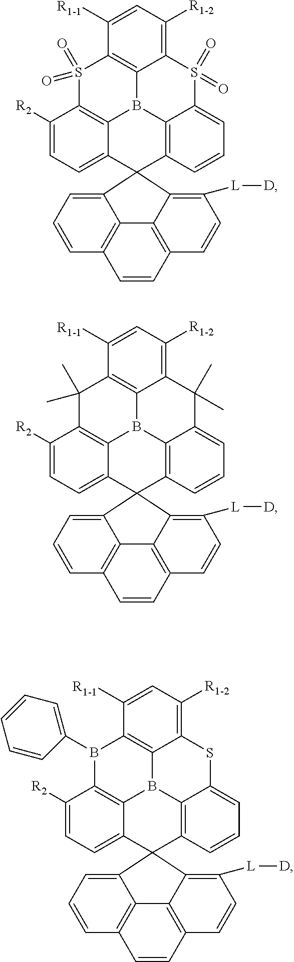

wherein, R₁₋₁, R₁₋₂ and R₂ are each independently selected from hydrogen, cyano; and the definitions of L and D are the same as the previous definitions.

In some embodiments, the compound of Formula 1 is selected from the following compounds:

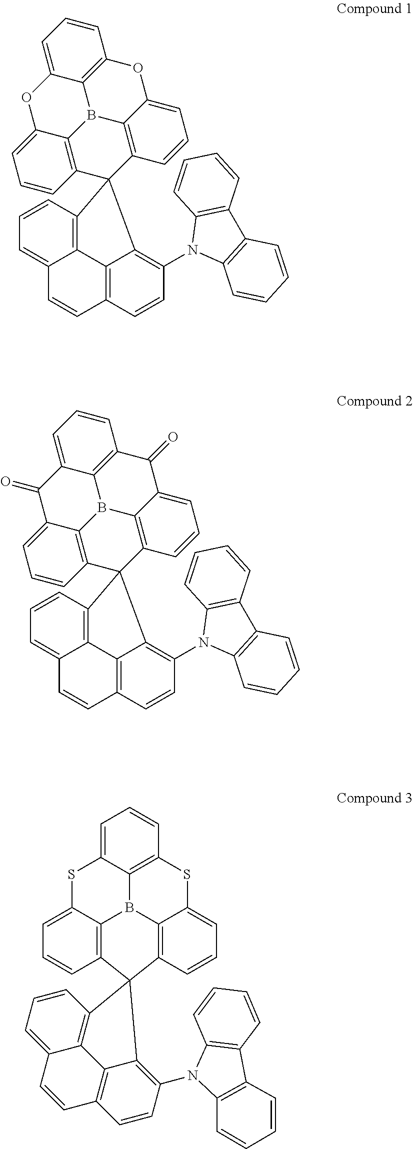 [SMILES: c1cc2c3c(c1)Oc1cccc4c1B3c1c(cccc1C41c3cccc4ccc5ccc(-n6c7ccccc7c7ccccc76)c1c5c34)O2 ; O=C1c2cccc3c2B2c4c1cccc4C1(c4cccc(c42)C3=O)c2cccc3ccc4ccc(-n5c6ccccc6c6ccccc65)c1c4c23 ; c1cc2c3c(c1)Sc1cccc4c1B3c1c(cccc1C41c3cccc4ccc5ccc(-n6c7ccccc7c7ccccc76)c1c5c34)S2]

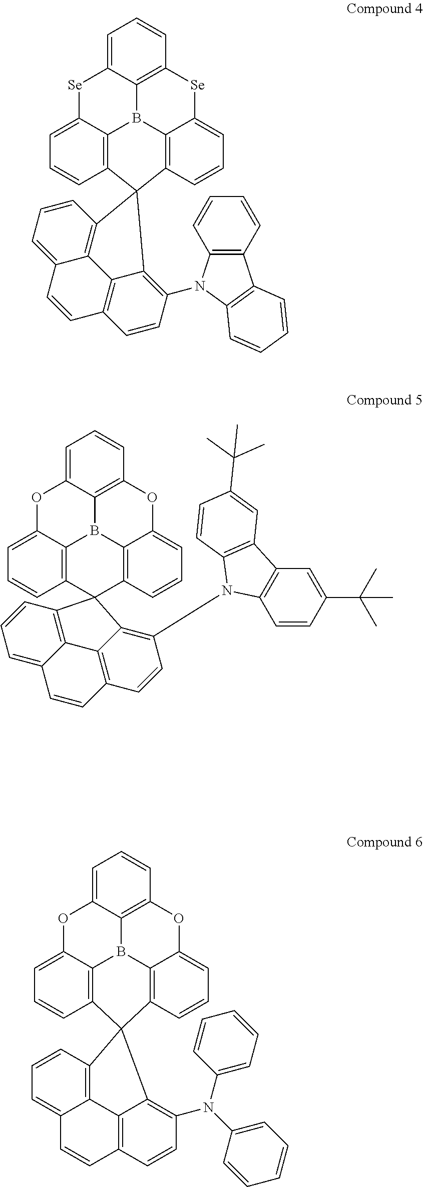 [SMILES: c1cc2c3c(c1)[Se]c1cccc4c1B3c1c(cccc1C41c3cccc4ccc5ccc(-n6c7ccccc7c7ccccc76)c1c5c34)[Se]2 ; CC(C)(C)c1ccc2c(c1)c1cc(C(C)(C)C)ccc1n2-c1ccc2ccc3cccc4c3c2c1C41c2cccc3c2B2c4c(cccc4Oc4cccc1c42)O3 ; c1ccc(N(c2ccccc2)c2ccc3ccc4cccc5c4c3c2C52c3cccc4c3B3c5c(cccc5Oc5cccc2c53)O4)cc1]

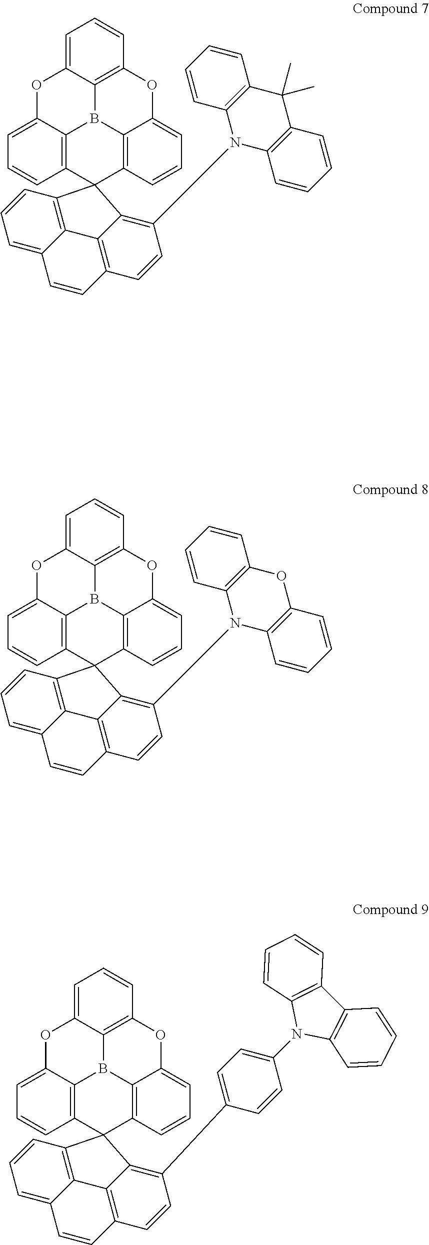 [SMILES: CC1(C)c2ccccc2N(c2ccc3ccc4cccc5c4c3c2C52c3cccc4c3B3c5c(cccc5Oc5cccc2c53)O4)c2ccccc21 ; c1ccc2c(c1)Oc1ccccc1N2c1ccc2ccc3cccc4c3c2c1C41c2cccc3c2B2c4c(cccc4Oc4cccc1c42)O3 ; c1cc2c3c(c1)Oc1cccc4c1B3c1c(cccc1C41c3cccc4ccc5ccc(-c6ccc(-n7c8ccccc8c8ccccc87)cc6)c1c5c34)O2]

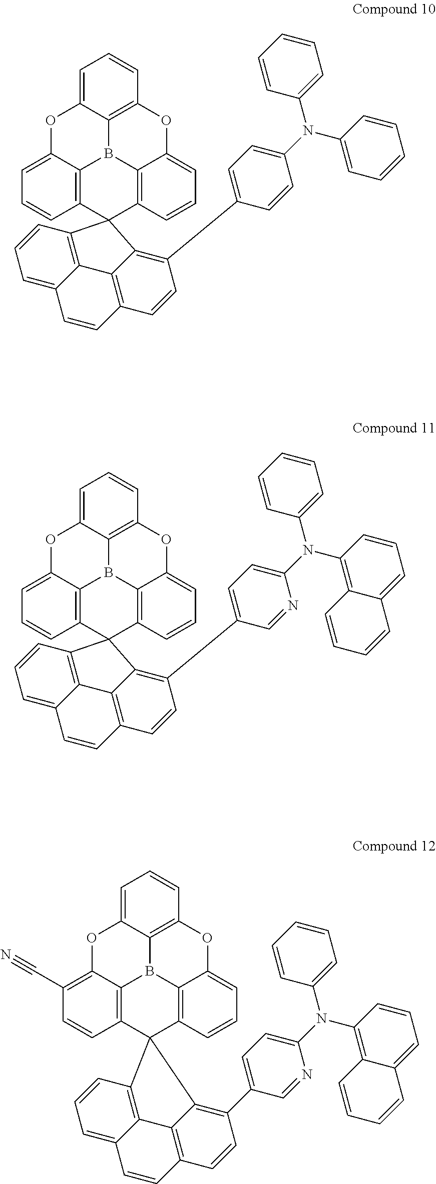 [SMILES: c1ccc(N(c2ccccc2)c2ccc(-c3ccc4ccc5cccc6c5c4c3C63c4cccc5c4B4c6c(cccc6Oc6cccc3c64)O5)cc2)cc1 ; c1ccc(N(c2ccc(-c3ccc4ccc5cccc6c5c4c3C63c4cccc5c4B4c6c(cccc6Oc6cccc3c64)O5)cn2)c2cccc3ccccc23)cc1 ; N#Cc1ccc2c3c1Oc1cccc4c1B3c1c(cccc1C21c2cccc3ccc5ccc(-c6ccc(N(c7ccccc7)c7cccc8ccccc78)nc6)c1c5c23)O4]

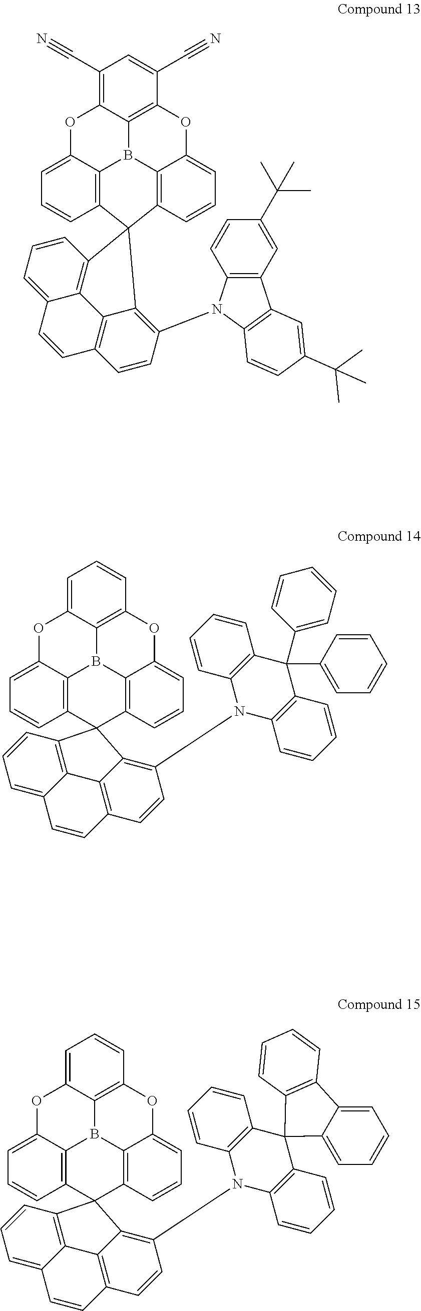 [SMILES: CC(C)(C)c1ccc2c(c1)c1cc(C(C)(C)C)ccc1n2-c1ccc2ccc3cccc4c3c2c1C41c2cccc3c2B2c4c(cccc41)Oc1c(C#N)cc(C#N)c(c12)O3 ; c1ccc(C2(c3ccccc3)c3ccccc3N(c3ccc4ccc5cccc6c5c4c3C63c4cccc5c4B4c6c(cccc6Oc6cccc3c64)O5)c3ccccc32)cc1 ; c1cc2c3c(c1)Oc1cccc4c1B3c1c(cccc1C41c3cccc4ccc5ccc(N6c7ccccc7C7(c8ccccc8-c8ccccc87)c7ccccc76)c1c5c34)O2]

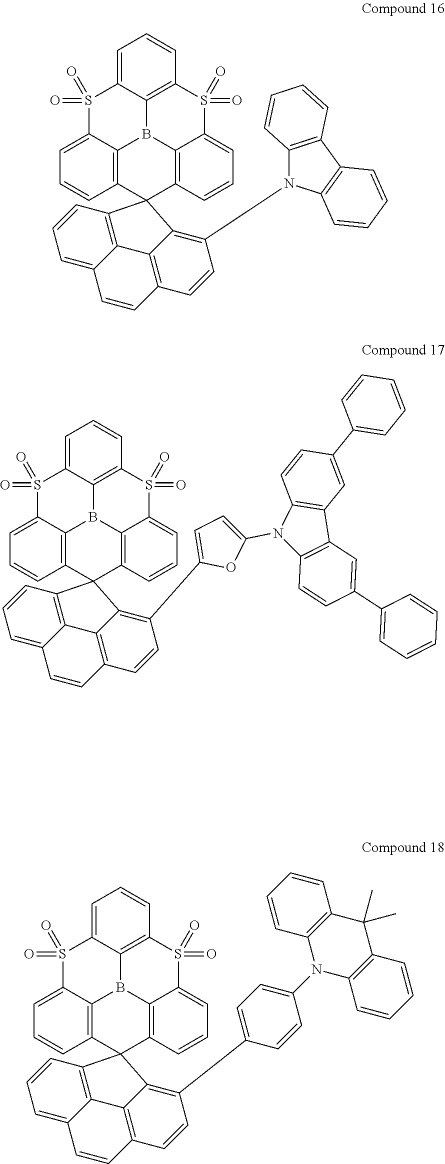 [SMILES: O=S1(=O)c2cccc3c2B2c4c(cccc4S(=O)(=O)c4cccc1c42)C31c2cccc3ccc4ccc(-n5c6ccccc6c6ccccc65)c1c4c23 ; O=S1(=O)c2cccc3c2B2c4c(cccc4S(=O)(=O)c4cccc1c42)C31c2cccc3ccc4ccc(-c5ccc(-n6c7ccc(-c8ccccc8)cc7c7cc(-c8ccccc8)ccc76)o5)c1c4c23 ; CC1(C)c2ccccc2N(c2ccc(-c3ccc4ccc5cccc6c5c4c3C63c4cccc5c4B4c6c3cccc6S(=O)(=O)c3cccc(c34)S5(=O)=O)cc2)c2ccccc21]

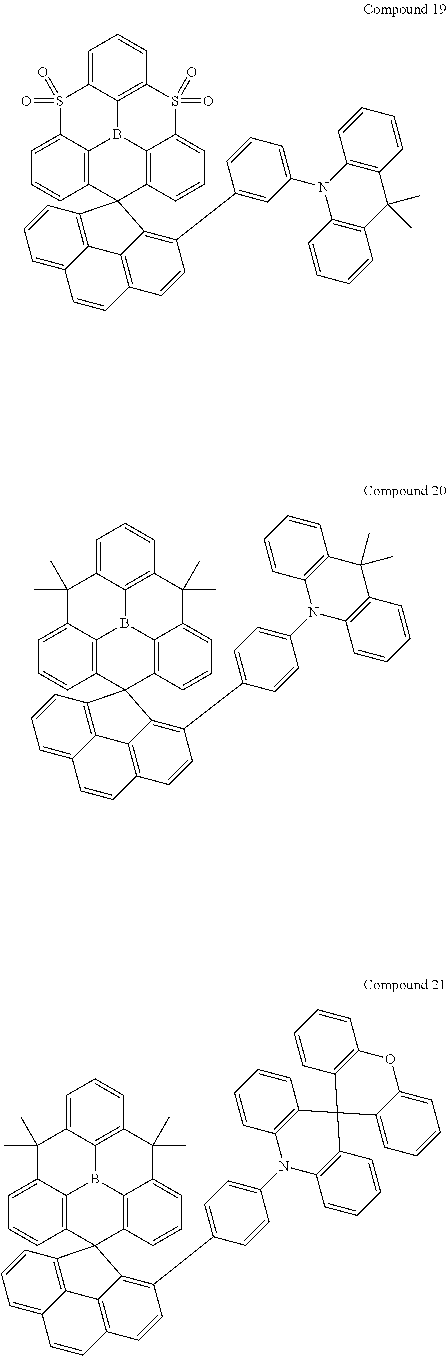 [SMILES: CC1(C)c2ccccc2N(c2cccc(-c3ccc4ccc5cccc6c5c4c3C63c4cccc5c4B4c6c3cccc6S(=O)(=O)c3cccc(c34)S5(=O)=O)c2)c2ccccc21 ; CC1(C)c2ccccc2N(c2ccc(-c3ccc4ccc5cccc6c5c4c3C63c4cccc5c4B4c6c(cccc6C(C)(C)c6cccc3c64)C5(C)C)cc2)c2ccccc21 ; CC1(C)c2cccc3c2B2c4c1cccc4C1(c4cccc(c42)C3(C)C)c2cccc3ccc4ccc(-c5ccc(N6c7ccccc7C7(c8ccccc8Oc8ccccc87)c7ccccc76)cc5)c1c4c23]

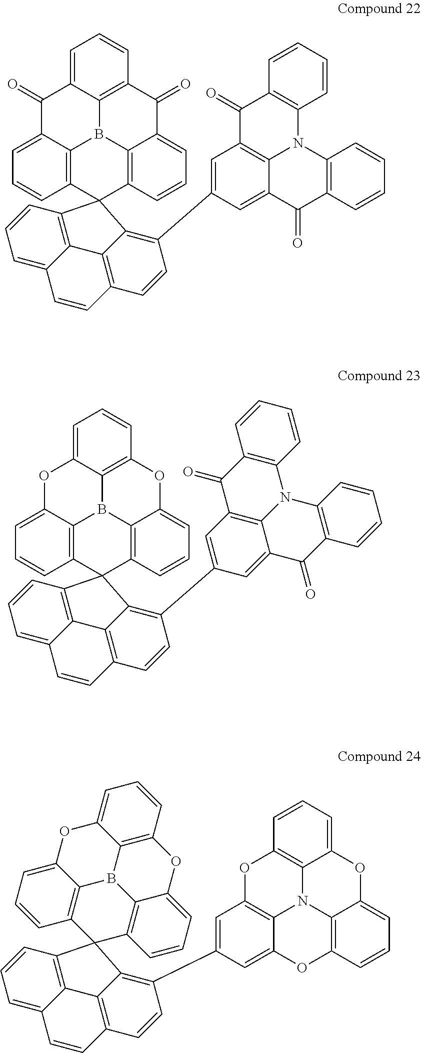 [SMILES: O=C1c2cccc3c2B2c4c1cccc4C1(c4cccc(c42)C3=O)c2cccc3ccc4ccc(-c5cc6c(=O)c7ccccc7n7c8ccccc8c(=O)c(c5)c67)c1c4c23 ; O=c1c2ccccc2n2c3ccccc3c(=O)c3cc(-c4ccc5ccc6cccc7c6c5c4C74c5cccc6c5B5c7c(cccc7Oc7cccc4c75)O6)cc1c32 ; c1cc2c3c(c1)Oc1cccc4c1B3c1c(cccc1C41c3cccc4ccc5ccc(-c6cc7c8c(c6)Oc6cccc9c6N8c6c(cccc6O7)O9)c1c5c34)O2]

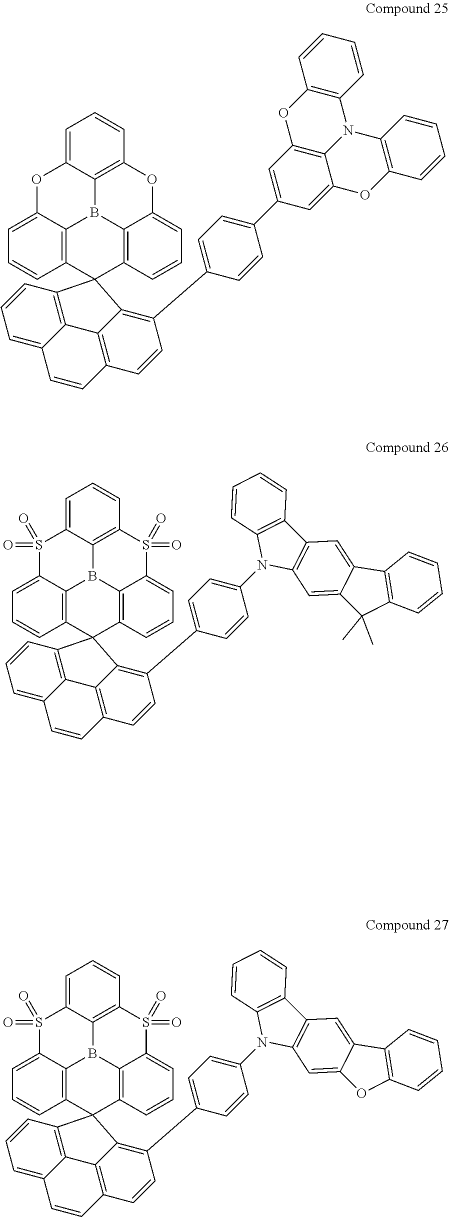 [SMILES: c1ccc2c(c1)Oc1cc(-c3ccc(-c4ccc5ccc6cccc7c6c5c4C74c5cccc6c5B5c7c(cccc7Oc7cccc4c75)O6)cc3)cc3c1N2c1ccccc1O3 ; CC1(C)c2ccccc2-c2cc3c4ccccc4n(-c4ccc(-c5ccc6ccc7cccc8c7c6c5C85c6cccc7c6B6c8c5cccc8S(=O)(=O)c5cccc(c56)S7(=O)=O)cc4)c3cc21 ; O=S1(=O)c2cccc3c2B2c4c(cccc4S(=O)(=O)c4cccc1c42)C31c2cccc3ccc4ccc(-c5ccc(-n6c7ccccc7c7cc8c(cc76)oc6ccccc68)cc5)c1c4c23]

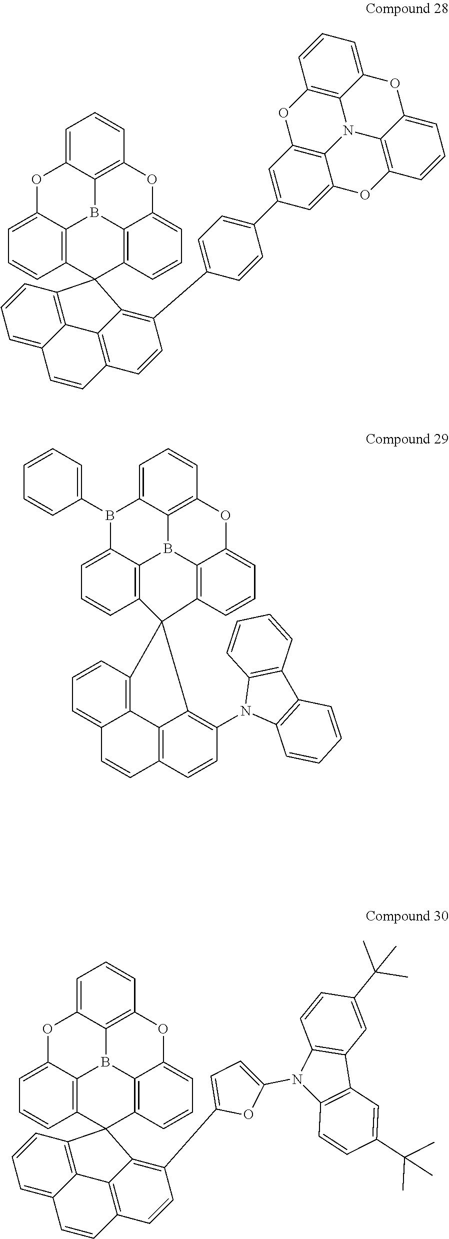 [SMILES: c1cc2c3c(c1)Oc1cccc4c1B3c1c(cccc1C41c3cccc4ccc5ccc(-c6ccc(-c7cc8c9c(c7)Oc7cccc%10c7N9c7c(cccc7O8)O%10)cc6)c1c5c34)O2 ; c1ccc(B2c3cccc4c3B3c5c(cccc5C5(c6cccc2c63)c2cccc3ccc6ccc(-n7c8ccccc8c8ccccc87)c5c6c23)O4)cc1 ; CC(C)(C)c1ccc2c(c1)c1cc(C(C)(C)C)ccc1n2-c1ccc(-c2ccc3ccc4cccc5c4c3c2C52c3cccc4c3B3c5c(cccc5Oc5cccc2c53)O4)o1]

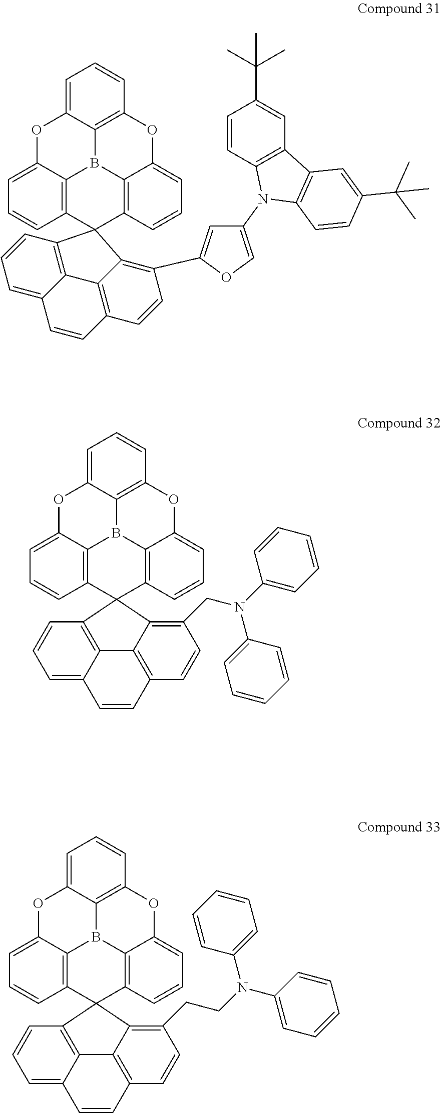 [SMILES: CC(C)(C)c1ccc2c(c1)c1cc(C(C)(C)C)ccc1n2-c1coc(-c2ccc3ccc4cccc5c4c3c2C52c3cccc4c3B3c5c(cccc5Oc5cccc2c53)O4)c1 ; c1ccc(N(Cc2ccc3ccc4cccc5c4c3c2C52c3cccc4c3B3c5c(cccc5Oc5cccc2c53)O4)c2ccccc2)cc1 ; c1ccc(N(CCc2ccc3ccc4cccc5c4c3c2C52c3cccc4c3B3c5c(cccc5Oc5cccc2c53)O4)c2ccccc2)cc1]

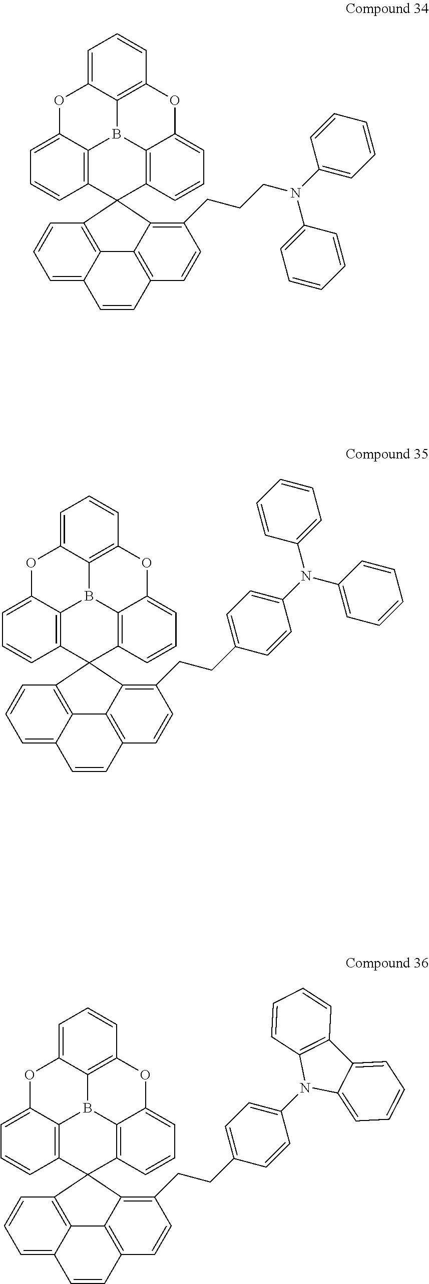 [SMILES: c1ccc(N(CCCc2ccc3ccc4cccc5c4c3c2C52c3cccc4c3B3c5c(cccc5Oc5cccc2c53)O4)c2ccccc2)cc1 ; c1ccc(N(c2ccccc2)c2ccc(CCc3ccc4ccc5cccc6c5c4c3C63c4cccc5c4B4c6c(cccc6Oc6cccc3c64)O5)cc2)cc1 ; c1cc2c3c(c1)Oc1cccc4c1B3c1c(cccc1C41c3cccc4ccc5ccc(CCc6ccc(-n7c8ccccc8c8ccccc87)cc6)c1c5c34)O2]

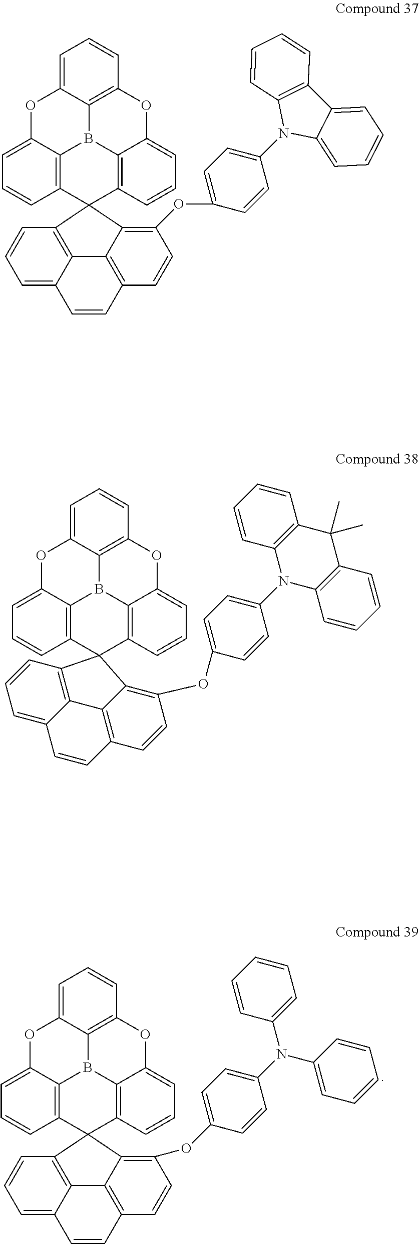 [SMILES: c1cc2c3c(c1)Oc1cccc4c1B3c1c(cccc1C41c3cccc4ccc5ccc(Oc6ccc(-n7c8ccccc8c8ccccc87)cc6)c1c5c34)O2 ; CC1(C)c2ccccc2N(c2ccc(Oc3ccc4ccc5cccc6c5c4c3C63c4cccc5c4B4c6c(cccc6Oc6cccc3c64)O5)cc2)c2ccccc21 ; c1ccc(N(c2ccccc2)c2ccc(Oc3ccc4ccc5cccc6c5c4c3C63c4cccc5c4B4c6c(cccc6Oc6cccc3c64)O5)cc2)cc1]

An embodiment of the present disclosure also provides a synthesis method of the compound of Formula 1 as described above, the synthesis method as shown in the following reaction equation 1 comprises:

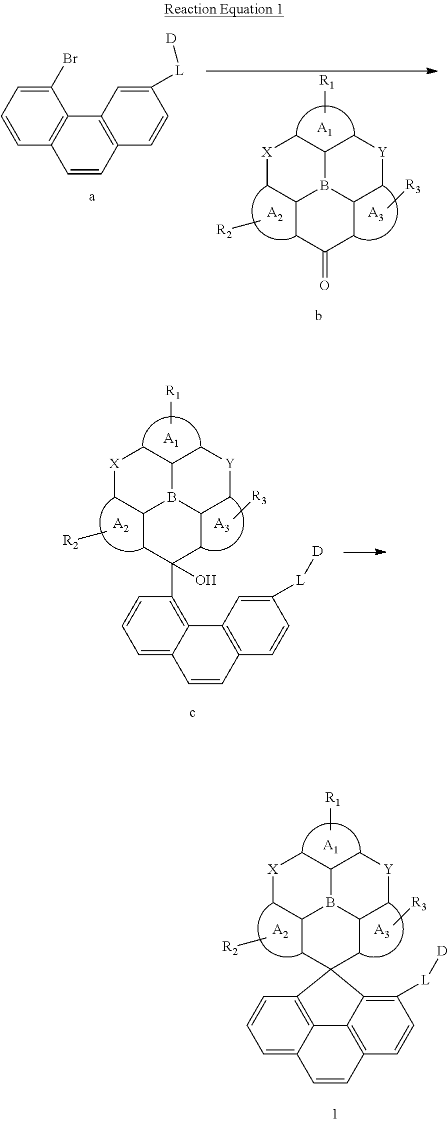

(1) reacting compound a with compound b to obtain compound c; and
(2) reacting the compound c to obtain a compound of Formula 1,
wherein, the definitions of each substituent are the same as the aforementioned definitions.

The above step (1) may be performed in the presence of n-butyl lithium in a solvent such as tetrahydrofuran (THF) under the protection of an inert gas such as nitrogen, but the present disclosure is not limited thereto.

The above step (2) may be performed in a mixed solution of acetic acid and concentrated hydrochloric acid, but the present disclosure is not limited thereto.

In some embodiments, compound a may be synthesized by one of the following methods, but is not limited thereto.

In method 1, when L is a direct bond:

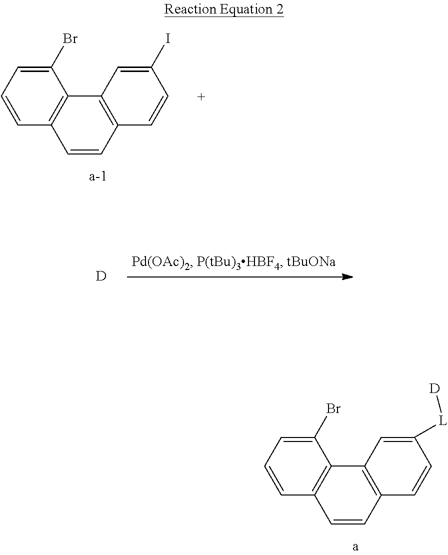

As shown in reaction formula 2, compound a-1 reacts with compound D (e.g., 9H-carbazole) to obtain compound a; the reaction may, for example, be carried out in palladium acetate (Pd(OAc)₂), tri-n-butyl phosphine tetrafluoroborate (P(tBu)₃·HBF₄), sodium tert-butoxide (tBuONa) in a solvent (e.g., toluene), but is not limited thereto;

In method 2, when L is an indirect bond:

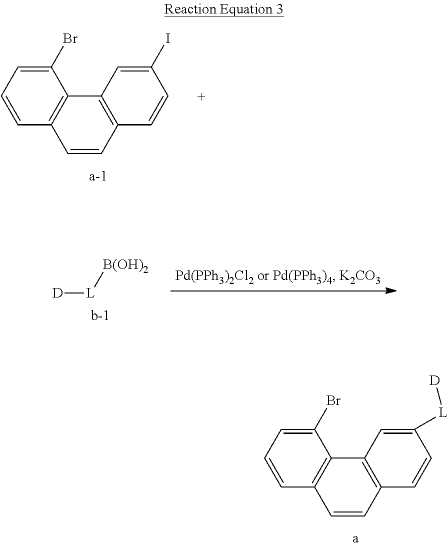

As shown in reaction equation 3, compound a-1 reacts with compound b-1 (e.g., 4-(9H-carbazol-9-yl) phenylboronic acid) to obtain compound a; the reaction may, for example, be carried out in the presence of bis(triphenyl)phosphine palladium dichloride (Pd(PPh₃)₂Cl₂) or tetra(triphenyl phosphine)palladium (Pd(PPh₃)₄), potassium carbonate (K₂CO₃) in a solvent (e.g., a mixed solvent of toluene, ethanol and water in a volume ratio of 3:1:1), but is not limited thereto.

In method 3, when D is diarylamine and L is a direct bond:

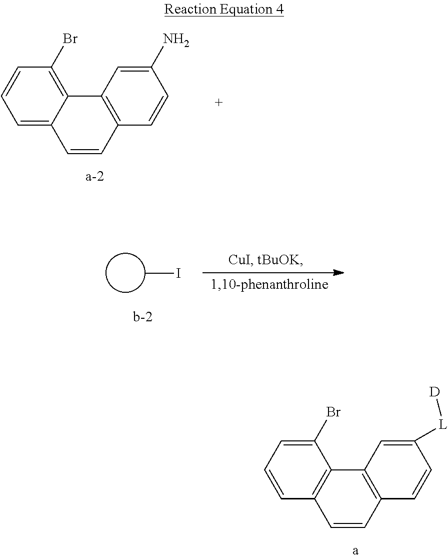

Herein, [symbol] represents a substituted aryl.

As shown in reaction equation 4, compound a-2 reacts with compound b-2 (e.g., iodobenzene) to obtain compound a; the reaction may, for example, be carried out in the presence of cuprous iodide (CuI), potassium tert-butoxide (tBuOK), 1,10-phenanthroline in a solvent (e.g., toluene), but is not limited thereto.

In addition, according to the structures of the compound of Formula 1 and the compound a of the present disclosure, a person skilled in the art can design a new synthetic route by referring to the known synthetic methods, so the synthetic methods of the compound of Formula 1 and the compound a are not limited to the above methods. The compounds of the present disclosure are TADF type organic luminescent materials with space charge transfer properties, and show good electroluminescent performances when used as guest luminescent materials or sensitizing materials for organic electroluminescent devices.

Another embodiment of the present disclosure provides the use of the compound of the present disclosure described above for the preparation of an organic luminescent material. In one embodiment, the organic luminescent material is a TADF type organic luminescent material. In another embodiment, the organic luminescent material is a guest material or a sensitizing material of a luminescent layer.

Still another embodiment of the present disclosure provides use of the compound of the present disclosure described above for the preparation of an organic electroluminescent device.

Still another embodiment of the present disclosure provides an organic electroluminescent device comprising a luminescent layer comprising the compound of the present disclosure described above.

It should be noted that in the organic electroluminescent device, the luminescent layer may be provided as one layer or as two or more layers. When the luminescent layers are disposed as two or more layers, the multiple luminescent layers may be stacked, and at least one luminescent layer includes the compound of the present disclosure.

The luminescent layer may also include other materials as desired.

In one embodiment, the compound of the present disclosure may serve as a guest material for the luminescent layer, which may also comprise a host material, such as DPEPO, but is not limited thereto. At this time, the weight percentage of the guest material in the luminescent layer may be 0.1% to 30%, but is not limited thereto.

In another embodiment, the compounds of the present disclosure may serve as a sensitizing material of the luminescent layer, and the luminescent material may also comprises a host material (e.g., CBP) and a luminescent dye (e.g., DCJTB) but is not limited thereto. At this time, the weight ratio of the host material, the sensitizing material and the luminescent dye in the luminescent layer may be 60-95:1-30:0.01-10, but is not limited thereto.

In addition to the luminescent layer, the organic electroluminescent device may include one or more layers of a cathode, an anode, an electron blocking layer, an electron transport layer, an electron injection layer, a hole injection layer, a hole transport layer, a hole barrier layer, a covering layer, an encapsulation layer, and the like, but is not limited thereto. The organic electroluminescent device may have the structure of a conventional organic electroluminescent device without particular limitation. For example, the organic electroluminescent device may have a structure of an anode/hole injection layer/hole transport layer/electron barrier layer/luminescent layer/hole barrier layer/electron transport layer/electron injection layer/cathode, but is not limited thereto.

In some embodiments, ITO glass is used as the anode and Ag:Mg composite electrode is used as the cathode.

In some embodiments, the material of the hole injection layer is HAT-CN; the material of the hole transport layer is NPB and/or TCTA; the material of the electron barrier layer is mCP; the material of the hole barrier layer is DPEPO; the material of the electron transport layer is TmPyPB; the material of the electron injection layer is LiF; and the host material of the luminescent layer is DPEPO.

In some embodiments, the material of the hole injection layer is HAT-CN; the material of the hole transport layer is NPB and/or TCTA; the material of the electron barrier layer is mCP; the material of the hole barrier layer is DPEPO; the material of the electron transport layer is TmPyPB; the material of the electron injection layer is LiF; the host material of the luminescent layer is CBP; and the luminescent dye is DCJTB.

The specific structure, material composition and preparation method of the cathode, anode, electron barrier layer, electron transport layer, electron injection layer, hole injection layer, hole transport layer, hole barrier layer, covering layer and encapsulation layer of the embodiments of the present disclosure may adopt any suitable structure, material composition and preparation method without particular limitation. The present disclosure does not relate to the improvements of these components and therefore these components are not described in detail to avoid obscuring the main technical ideas of the present disclosure.

A still another embodiment of the present disclosure provides a display device including an organic electroluminescent device according to the present disclosure.

In some embodiments, the display device may include a plurality of organic electroluminescent devices, at least one of which is an organic electroluminescent device according to the present disclosure. For example, the organic electroluminescent device in the display device may be a blue, green, or red organic electroluminescent device, but is not limited thereto.

The above display device of the present disclosure may be any product or component with a display function, such as a mobile phone, a tablet computer, a television, a display, a notebook computer, a digital photo frame, a navigator, a vehicle-mounted display, a smart watch or a smart bracelet and the like. Other essential components of the display device should be understood as being included in the display device by those of ordinary skill in the art, which will not be described herein in detail, and should not be regarded as a limitation on the present invention.

In the present disclosure, the words “including” or variations thereof, such as “comprising”, “containing”, “having” will be understood to include the stated elements, integers or steps, or combination of elements, integers or steps, but does not preclude the addition of other elements, integers or steps, or combination of elements, integers or steps.

Unless otherwise defined, all technical and scientific terms used herein have the same meanings as those of ordinary skill in the art to which the invention pertains. Although those similar to or equivalent to the methods and materials described herein may be used in the practice or testing of the present invention, suitable methods and materials will be described below. In case of conflict, this specification (including definitions) will control. In addition, the materials, methods and embodiments are only illustrative and not intended to be limiting.

“At least one of A, B and C” has the same meaning as “at least one of A, B or C” and includes the following combinations of A, B and C: A only, B only, C only, a combination of A and B, a combination of A and C, a combination of B and C, and a combination of A, B and C.

“A and/or B” includes the following three combinations: A only, B only, and a combination of A and B.

In the present disclosure, “multiple” means two or more than two, unless otherwise specified. In the present disclosure, a TADF type organic luminescent material with space charge transfer properties is developed by fixing a boron-containing fused ring with a spirocyclic phenanthrene fluorine group to construct receptor units with rigid structures, and limiting different donor units to the phenanthrene based linker to achieve a tightly stacked coplanar conformation, forming a tightly stacked structure between the donor and acceptor of the luminescent material molecule; and was used as a luminescent material in organic electroluminescent device. In some embodiments, doped OLED device is fabricated by vacuum evaporation method, which realizes the performance of OLED device such as high efficiency, low operating voltage and long service life and the like.

### EXAMPLES

A synthesis process of a compound containing a benzoheterocyclic structure of some exemplary embodiments of the present disclosure and results of testing and comparing the properties of the prepared electroluminescent device are provided below.

### Synthesis Example 1: Synthesis of Compound 1

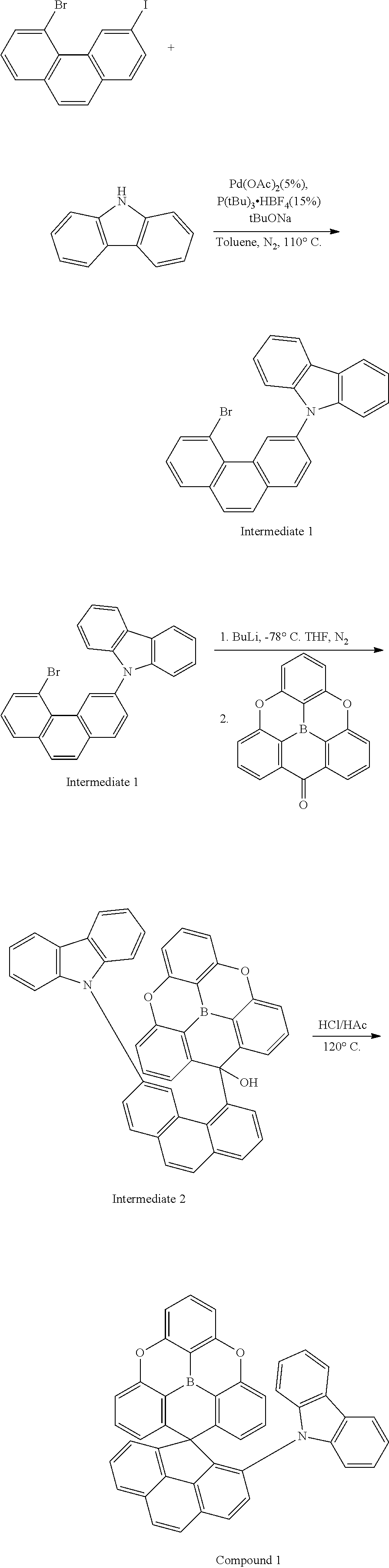

### Synthesis of Intermediate 1

5-bromo-3-iodo-phenanthrene (4.58 g, 12 mmol), 9H-carbazole (1.67 g, 10 mmol), palladium acetate (112 mg, 0.5 mmol), tri-n-butyl phosphine tetrafluoroborate (480 mg, 1.5 mmol), sodium tert-butoxide (2.9 g, 30 mmol) and toluene (60 mL) were added into a round bottom flask in turn, heated to 110° C., and reacted for 24 h at reflux under the protection of nitrogen. During the reaction, the reaction was monitored by TLC thin plate, until the reaction was complete, and then the reaction solution was cooled to room temperature, rotated and evaporated to dryness, and extracted with dichloromethane. The organic phase was washed with deionized water, dried with anhydrous sodium sulfate, the solvent was rotated and evaporated to dryness, and the sample was mixed. It was separated by chromatography on silica gel column to obtain the intermediate 1, which was 3.28 g solid powder with a yield of 65%. ¹H NMR (500 MHz, Chloroform-D) δ 8.55 (s, 1H), 8.29 (s, 1H), 8.19 (s, 1H), 7.97-7.79 (m, 4H), 7.76 (d, J=10.6 Hz, 2H), 7.52 (s, 2H), 7.40 (s, 1H), 7.23-7.14 (m, 3H), 7.11 (s, 1H).

### Synthesis of Intermediate 2

The intermediate 1 (2.10 g, 5 mmol) was dissolved in 30 mL of anhydrous tetrahydrofuran, added into a two-necked flask under the protection of argon, cooled to −78° C. and stirred for 10 min. N-butyl lithium (1.6 mol/L, THF, 4.5 mL) was slowly added dropwise with a syringe, and stirred at −78° C. for 1 h. Then 12H-4,8-dioxa-3a²-boroxadibenzo[cd,mn]pyrene-12-one (4.45 g, 15 mmol) dissolved in anhydrous tetrahydrofuran, and then added into the flask. The temperature was raised to room temperature and the reaction was carried out for 24 hour with continuously stirring under the protection of argon. The reaction was monitored by TLC thin plate, until the reaction was complete. The reaction solution was rotated and evaporated to dryness and the sample was mixed. It was separated by chromatography on silica gel column to obtain the intermediate 2, which was 2.64 g solid powder with a yield of 85%. ¹H NMR (500 MHz, Chloroform-D) δ 8.55 (s, 1H), 8.36 (s, 1H), 8.19 (s, 1H), 7.92 (s, 2H), 7.90-7.82 (m, 3H), 7.77 (s, 1H), 7.66 (s, 1H), 7.52 (s, 1H), 7.40 (s, 1H), 7.31 (s, 1H), 7.26-7.09 (m, 6H), 7.06 (s, 2H), 6.94 (s, 2H), 6.69 (s, 2H), 2.08 (s, 1H).

### Synthesis of compound 1

Intermediate 2 (2 g, 3.13 mmol), acetic acid (60 mL) and concentrated hydrochloric acid (5 mL) were added into a round bottom flask, heated to 120° C., and the reaction was carried out at reflux under the protection of nitrogen. The reaction was monitored by TLC thin plate, until the reaction was complete. The reaction solution was cooled to room temperature, rotated and evaporated to dryness, and extracted with dichloromethane. The organic phase was washed with water, dried with anhydrous sodium sulfate, the solvent was rotated and evaporated to dryness, and the samples were mixed. It was separated by chromatography on silica gel column to obtain the compound 1, which was 1.17 g solid powder with a yield of 60%. ¹H NMR (500 MHz, Chloroform-D) δ 8.55 (s, 1H), 8.18 (t, J=10.3 Hz, 3H), 7.92 (s, 2H), 7.80 (s, 1H), 7.62 (s, 1H), 7.52-7.33 (m, 3H), 7.31 (s, 1H), 7.18 (m, 5H), 7.11 (s, 1H), 6.96 (s, 2H), 6.87 (s, 2H), 6.69 (s, 2H).

### Synthesis Example 2: Synthesis of Compound 2

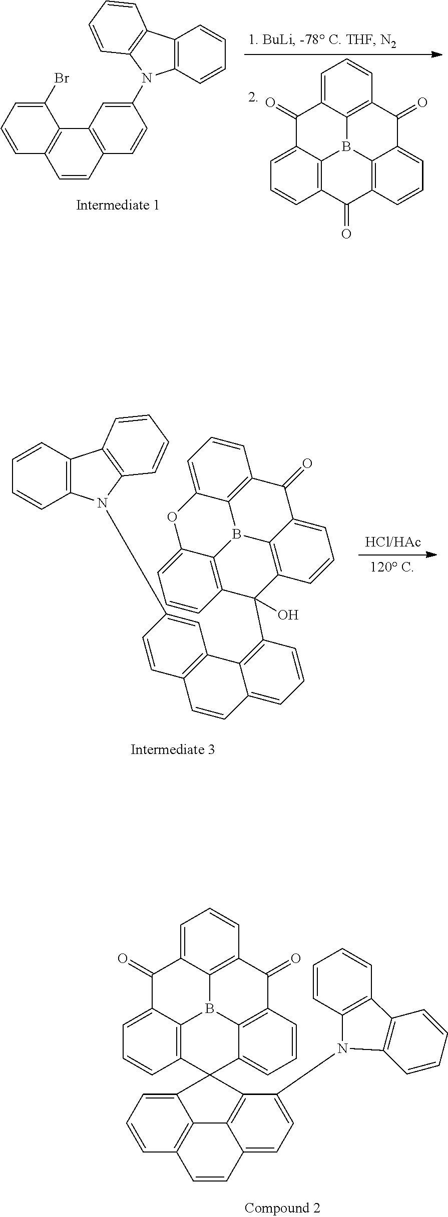 [SMILES: Brc1cccc2ccc3ccc(-n4c5ccccc5c5ccccc54)cc3c12 ; O=C1c2cccc3c2B2c4c1cccc4C(=O)c1cccc(c12)C3=O ; O=C1c2cccc3c2B2c4c(cccc4C(O)(c4cccc5ccc6ccc(-n7c8ccccc8c8ccccc87)cc6c45)c4cccc1c42)O3 ; O=C1c2cccc3c2B2c4c1cccc4C1(c4cccc(c42)C3=O)c2cccc3ccc4ccc(-n5c6ccccc6c6ccccc65)c1c4c23]

### Synthesis of Intermediate 3

The intermediate 1 (2.10 g, 5 mmol) was dissolved in 30 mL of anhydrous tetrahydrofuran, added to a double-neck flask under the protection of argon, and cooled to −78° C. and stirred for 10 min. N-butyl lithium (1.6 mol/L, THF, 4.5 mL) was slowly added dropwise with a syringe, stirred at −78° C. for 1 h. Then 4H-3a²-boroxadibenzo[cd,mn]pyrene-4,8,12-one (4.8 g, 15 mmol) dissolved in anhydrous tetrahydrofuran, and then added into the flask. The temperature was raised to room temperature and the reaction was carried out for 24 hour with continuously stirring under the protection of argon. The reaction was monitored by TLC thin plate, until the reaction was complete. The reaction solution was rotated and evaporated to dryness and the sample was mixed. It was separated by chromatography on silica gel column to obtain the intermediate 3, which was 2.39 g solid powder with a yield of 72%. ¹H NMR (500 MHz, Chloroform-D) δ 8.55 (s, 1H), 8.41 (s, 1H), 8.31-8.15 (m, 3H), 8.08 (s, 1H), 8.00-7.81 (m, 9H), 7.64 (m, 3H), 7.59-7.49 (m, 2H), 7.38 (m, 3H), 7.16 (m, 2H), 2.27 (s, 1H).

### Synthesis of Compound 2

The intermediate 3 (2 g, 3.02 mmol), acetic acid (60 mL) and concentrated hydrochloric acid (5 mL) were added into a round-bottom flask, heated to 120° C., and the reaction was carried out at reflux under the protection of nitrogen. The reaction was monitored by TLC thin plate, until the reaction was complete. The reaction solution was cooled to room temperature, rotated and evaporated to dryness, and extracted with dichloromethane. The organic phase was washed with water, dried with anhydrous sodium sulfate, the solvent was rotated and evaporated to dryness, and the samples were mixed. It was separated by chromatography on silica gel column to obtain the compound 2, which was 1.29 g solid powder with a yield of 66%. ¹H NMR (500 MHz, Chloroform-D) δ 8.55 (s, 1H), 8.19 (s, 1H), 8.15 (d, J=3.6 Hz, 2H), 8.11 (s, 1H), 7.92 (s, 2H), 7.85 (s, 2H), 7.80 (s, 1H), 7.62 (s, 1H), 7.58-7.48 (m, 4H), 7.41 (m, 3H), 7.33 (s, 2H), 7.27-7.14 (m, 3H), 7.11 (s, 1H).

### Synthesis Example 3: Synthesis of Compound 6

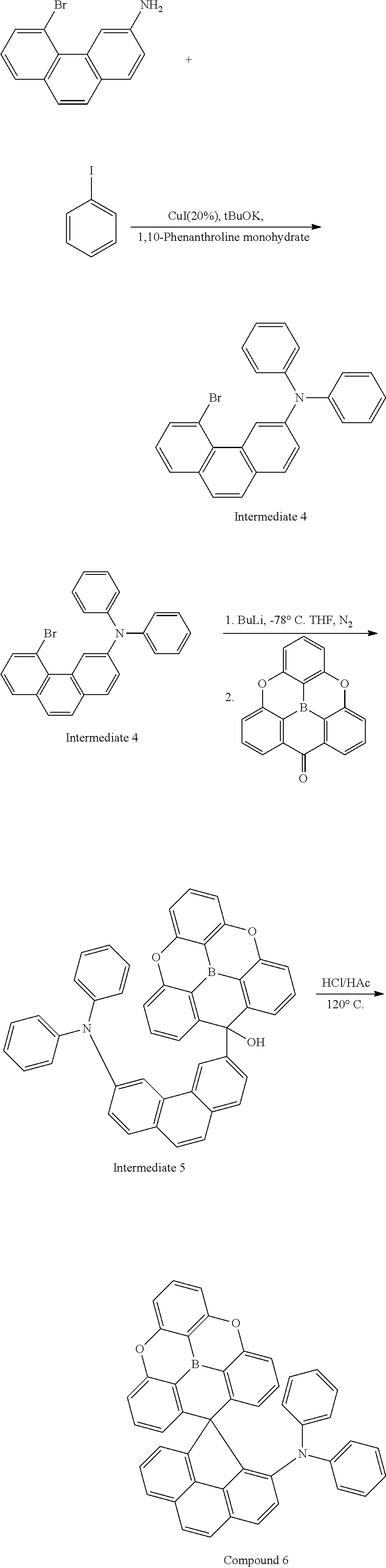

### Synthesis of Intermediate 4

5-bromo-phenanthrene-3-amine (3.25 g, 12 mmol), iodobenzene (4.9 g, 24 mmol), cuprous iodide (456 mg, 2.4 mmol), potassium tert-butoxide (2.24 g, 20 mmol), 1,10-phenanthroline (495 mg, 2.5 mmol) and toluene (60 mL) were added into a round-bottom flask in turn, and the temperature was raised to 110° C., and the reaction was carried out for 24 h at reflux under the protection of nitrogen. During the reaction, the reaction was monitored by TLC thin plate, until the reaction was complete. Then the reaction solution was cooled to room temperature, rotated and evaporated to dryness, and extracted with dichloromethane. The organic phase was washed with deionized water, and dried with anhydrous sodium sulfate, the solvent was rotated and evaporated to dryness, and the samples were mixed. It was separated by chromatography on silica gel column to obtain the compound 4, which was 3.3 g solid powder with a yield of 65%. ¹H NMR (500 MHz, Chloroform-D) δ 8.92 (s, 1H), 8.07 (s, 1H), 7.92 (s, 1H), 7.84 (d, J=5.0 Hz, 2H), 7.75 (s, 1H), 7.61 (s, 1H), 7.52 (s, 1H), 7.24 (s, 4H), 7.08 (s, 4H), 7.00 (s, 2H).

### Synthesis of Intermediate 5

The intermediate 4 (2.12 g, 5 mmol) was dissolved in 30 mL anhydrous tetrahydrofuran, and added to a double-neck flask under the protection of argon, and cooled to −78° C. and stirred for 10 min. N-butyl lithium (1.6 mol/L, THF, 4.5 mL) was slowly added dropwise with a syringe, and stirred at −78° C. for 1 h. Then 12H-4,8-dioxa-3a²-boroxadibenzo[cd,mn]pyrene-12-one (4.45 g, 15 mmol) dissolved in anhydrous tetrahydrofuran, and then added into the flask. The temperature was raised to room temperature and the reaction was carried out for 24 hour with continuously stirring under the protection of argon. The reaction was monitored by TLC thin plate, until the reaction was complete. The reaction solution was rotated and evaporated to dryness and the sample was mixed. It was separated by chromatography on silica gel column to obtain the intermediate 5, which was 2.24 g solid powder with a yield of 70%. ¹H NMR (500 MHz, Chloroform-D) δ 8.60 (s, 1H), 8.07 (s, 1H), 7.92 (s, 1H), 7.87 (s, 1H), 7.82 (s, 1H), 7.75 (s, 1H), 7.66 (d, J=3.0 Hz, 2H), 7.31 (s, 1H), 7.22 (m, 6H), 7.07 (d, J=10.0 Hz, 6H), 7.00 (s, 2H), 6.94 (s, 2H), 6.69 (s, 2H), 2.54 (s, 1H).

### Synthesis of compound 6

The intermediate 5 (2 g, 3.02 mmol), acetic acid (60 mL) and concentrated hydrochloric acid (5 mL) were added into a round bottom flask, heated to 120° C., and the reaction was carried out at reflux under the protection of nitrogen. The reaction was monitored by TLC thin plate, until the reaction was complete. The reaction solution was cooled to room temperature, rotated and evaporated to dryness, and extracted with dichloromethane. The organic phase was washed with water, dried with anhydrous sodium sulfate, the solvent was rotated and evaporated to dryness, and the samples were mixed. It was separated by chromatography on silica gel column to obtain the compound 6, which was 934 mg solid powder with a yield of 75%. ¹H NMR (500 MHz, Chloroform-D) δ 7.97 (s, 1H), 7.92 (s, 2H), 7.81 (d, J=7.5 Hz, 2H), 7.62 (s, 1H), 7.41 (s, 1H), 7.31 (s, 1H), 7.24 (s, 4H), 7.17 (s, 1H), 7.08 (s, 4H), 7.00 (s, 2H), 6.96 (s, 3H), 6.87 (s, 2H), 6.69 (s, 2H).

### Synthesis Example 4: Synthesis of Compound 7

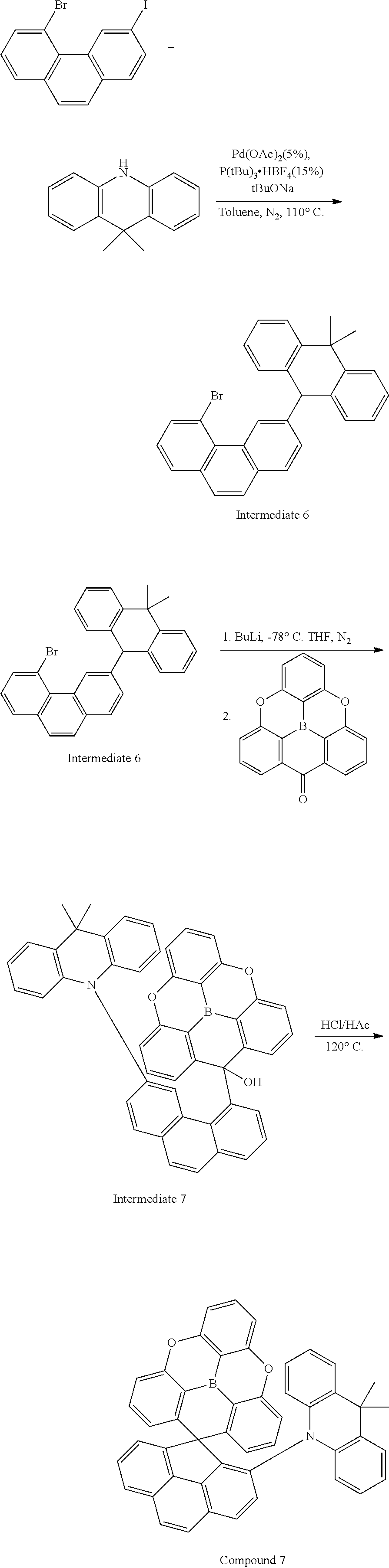

### Synthesis of Intermediate 6

5-bromo-3-iodo-phenanthrene (4.58 g, 12 mmol), 9,9-dimethyl-10H-acridine (2.5 g, 12 mmol), palladium acetate (112 mg, 0.5 mmol), tri-n-butyl phosphine tetrafluoroborate (480 mg, 1.5 mmol), sodium tert-butoxide (2.9 g, 30 mmol) and toluene (60 mL) were added into a round bottom flask in turn, heated to 110° C., and the reaction was carried out at reflux under the protection of nitrogen. During the reaction, the reaction was monitored by TLC thin plate, until the reaction was complete. The reaction solution was then cooled to room temperature, and rotated and evaporated to dryness, and extracted with dichloromethane. The organic phase was washed with deionized water, dried with anhydrous sodium sulfate, the solvent was rotated and evaporated to dryness, and the samples were mixed. It was separated by chromatography on silica gel column to obtain the intermediate 6, which was 3.78 g solid powder with a yield of 68%. ¹H NMR (500 MHz, Chloroform-D) δ 9.30 (s, 1H), 8.07 (s, 1H), 7.96-7.71 (m, 5H), 7.52 (s, 1H), 7.26-7.12 (m, 6H), 6.94 (s, 2H), 1.69 (s, 6H).

### Synthesis of Intermediate 7

The intermediate 6 (2.3 g, 5 mmol) was dissolved in 30 mL anhydrous tetrahydrofuran, and added to a double-neck flask under the protection of argon, and cooled to −78° C. and stirred for 10 min. N-butyl lithium (1.6 mol/L, THF, 4.5 mL) was slowly added dropwise with a syringe, and stirred at −78° C. for 1 h. Then 12H-4,8-dioxa-3a²-boroxadibenzo[cd,mn]pyrene-12-one (4.45 g, 15 mmol) dissolved in anhydrous tetrahydrofuran, and then added into the flask. The temperature was raised to room temperature and the reaction was carried out for 24 hour with continuously stirring under the protection of argon. The reaction was monitored by TLC thin plate, until the reaction was complete. The reaction solution was rotated and evaporated to dryness and the sample was mixed. It was separated by chromatography on silica gel column to obtain the intermediate 7, which was 2.68 g solid powder with a yield of 84%. ¹H NMR (500 MHz, Chloroform-D) δ 8.86 (s, 1H), 8.06 (s, 1H), 7.97-7.82 (m, 4H), 7.74 (s, 1H), 7.65 (s, 1H), 7.39-7.10 (m, 9H), 7.05 (s, 2H), 6.93 (s, 4H), 6.68 (s, 2H), 2.30 (s, 1H), 1.69 (s, 6H).

### Synthesis of Compound 7

The intermediate 7 (2.04 g, 3.0 mmol), acetic acid (60 mL) and concentrated hydrochloric acid (5 mL) were added into a round bottom flask, heated to 120° C., and the reaction was carried out at reflux under the protection of nitrogen. The reaction was monitored by TLC thin plate, until the reaction was complete. The reaction solution was cooled to room temperature, rotated and evaporated to dryness, and extracted with dichloromethane. The organic phase was washed with water, dried with anhydrous sodium sulfate, the solvent was rotated and evaporated to dryness, and the samples were mixed. It was separated by chromatography on silica gel column to obtain the compound 7, which was 1.35 g solid powder with a yield of 68%. ¹H NMR (500 MHz, Chloroform-D) δ 8.15 (s, 1H), 7.98 (d, J=7.5 Hz, 2H), 7.92 (s, 2H), 7.80 (s, 1H), 7.62 (s, 1H), 7.31 (s, 1H), 7.23-7.13 (m, 8H), 6.95 (d, J=10.0 Hz, 4H), 6.87 (s, 2H), 6.69 (s, 2H), 1.69 (s, 6H).

### Synthesis Example 5: Synthesis of Compound 9

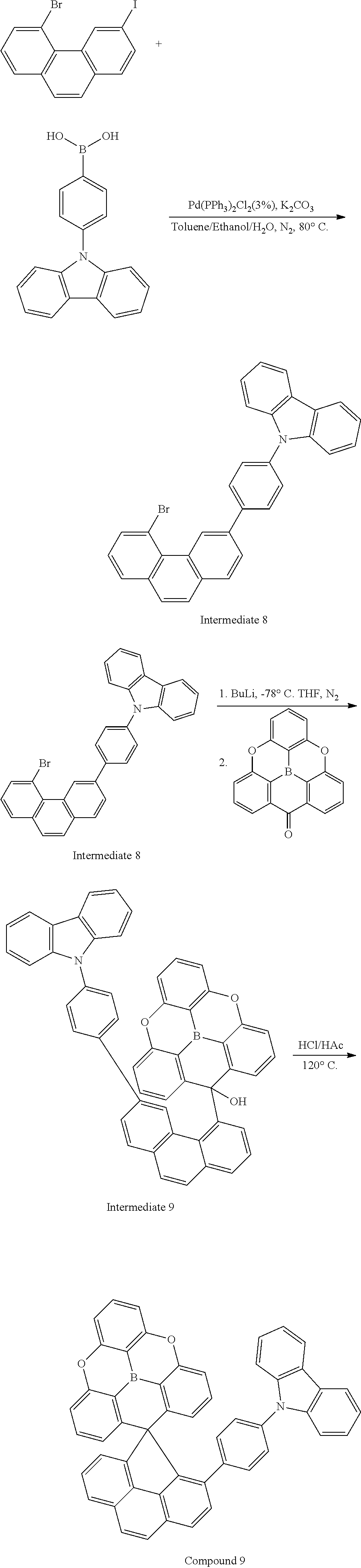

### Synthesis of Intermediate 8

5-bromo-3-iodo-phenanthrene (4.58 g, 12 mmol), 4-(9H-carbazol-9-yl) phenylboronic acid (3.45 g, 12 mmol), Pd(PPh₃)₂Cl₂ (350 mg, 0.5 mmol), potassium carbonate (1.6 g, 12 mmol), toluene:ethanol:water (30 mL: 10 mL: 10 mL) were added into a round bottom flask in turn, heated to 80° C., and the reaction was carried out for 24 h at reflux under the protection of nitrogen. During the reaction, the reaction was monitored by TLC thin plate, until the reaction was complete. The reaction solution was then cooled to room temperature, and rotated and evaporated to dryness, and extracted with dichloromethane and water. The organic phase was washed with deionized water, dried with anhydrous sodium sulfate, the solvent was rotated and evaporated to dryness, and the samples were mixed. It was separated by chromatography on silica gel column to obtain the intermediate 8, which was 3.58 g solid powder with a yield of 60%. ¹H NMR (500 MHz, Chloroform-D) δ 8.55 (s, 1H), 8.41 (s, 1H), 8.32-8.15 (m, 3H), 8.08 (s, 1H), 7.91 (d, J=5.0 Hz, 5H), 7.84 (d, J=2.3 Hz, 2H), 7.52 (s, 2H), 7.40 (s, 1H), 7.16 (m, 4H).

### Synthesis of Intermediate 9

The intermediate 8 (2.50 g, 5 mmol) was dissolved in 30 mL anhydrous tetrahydrofuran, and added to a double-neck flask under the protection of argon, and cooled to −78° C. and stirred for 10 min. N-butyl lithium (1.6 mol/L, THF, 4.5 mL) was slowly added dropwise with a syringe, and stirred at −78° C. for 1 h. Then 12H-4,8-dioxa-3a²-boroxadibenzo[cd,mn]pyrene-12-one (4.45 g, 15 mmol) dissolved in anhydrous tetrahydrofuran, and then added into the flask. The temperature was raised to room temperature and the reaction was carried out for 24 hour with continuously stirring under the protection of argon. The reaction was monitored by TLC thin plate, until the reaction was complete. The reaction solution was rotated and evaporated to dryness and the sample was mixed. It was separated by chromatography on silica gel column to obtain the intermediate 9, which was 2.86 g solid powder with a yield of 80%. ¹H NMR (500 MHz, Chloroform-D) δ 8.55 (s, 1H), 8.41 (s, 1H), 8.33-8.15 (m, 3H), 8.08 (s, 1H), 7.99-7.81 (m, 7H), 7.66 (s, 1H), 7.52 (s, 1H), 7.40 (s, 1H), 7.31 (s, 1H), 7.26-7.09 (m, 6H), 7.06 (s, 2H), 6.94 (s, 2H), 6.69 (s, 2H), 2.07 (s, 1H).

### Synthesis of Compound 9

The intermediate 9 (2 g, 3.13 mmol), acetic acid (60 mL) and concentrated hydrochloric acid (5 mL) were added into a round-bottom flask, heated to 120° C., and the reaction was carried out at reflux under the protection of nitrogen. The reaction was monitored by TLC thin plate, until the reaction was complete. The reaction solution was cooled to room temperature, rotated and evaporated to dryness, and extracted with dichloromethane. The organic phase was washed with water, dried with anhydrous sodium sulfate, the solvent was rotated and evaporated to dryness, and the samples were mixed. It was separated by chromatography on silica gel column to obtain the compound 9, which was 1.44 g solid powder with a yield of 66%. ¹H NMR (500 MHz, Chloroform-D) δ 8.55 (s, 1H), 8.42 (s, 1H), 8.19 (s, 1H), 8.14 (s, 1H), 7.94-7.76 (m, 7H), 7.62 (s, 1H), 7.52 (s, 1H), 7.40 (d, J=4.0 Hz, 2H), 7.31 (s, 1H), 7.18 (m, 5H), 7.11 (s, 1H), 6.96 (s, 2H), 6.87 (s, 2H), 6.69 (s, 2H).

### Synthesis Example 6: Synthesis of Compound 10

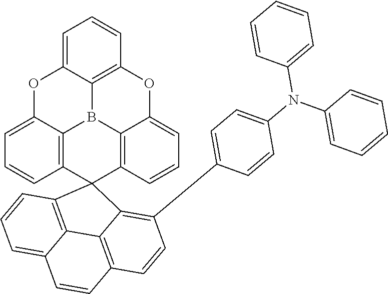 [SMILES: c1ccc(N(c2ccccc2)c2ccc(-c3ccc4ccc5cccc6c5c4c3C63c4cccc5c4B4c6c(cccc6Oc6cccc3c64)O5)cc2)cc1]

Compound 10 was synthesized in the same method as that in synthesis example 5 except that 4-(9H-carbazol-9-yl) phenylboronic acid was replaced by 4-(diphenylamino) phenylboronic acid. ¹H NMR (500 MHz, Chloroform-D) δ 8.42 (s, 1H), 8.21 (s, 1H), 8.14 (s, 1H), 7.92 (s, 2H), 7.80 (s, 1H), 7.62 (s, 1H), 7.55 (s, 2H), 7.41-7.37 (m, 1H), 7.31 (s, 1H), 7.27 (dd, J=7.5, 4.8 Hz, 1H), 7.24 (s, 2H), 7.23-7.18 (m, 2H), 7.17 (s, 2H), 7.08 (s, 2H), 7.08-7.04 (m, 2H), 7.00 (s, 1H), 6.96 (s, 2H), 6.94 (d, J=3.1 Hz, 1H), 6.87 (s, 1H), 6.85 (d, J=3.1 Hz, 1H), 6.69 (s, 2H).

### Synthesis Example 7: Synthesis of Compound 18

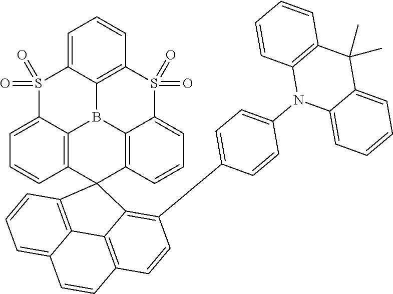 [SMILES: CC1(C)c2ccccc2N(c2ccc(-c3ccc4ccc5cccc6c5c4c3C63c4cccc5c4B4c6c3cccc6S(=O)(=O)c3cccc(c34)S5(=O)=O)cc2)c2ccccc21]

Compound 18 was synthesized in the same method as that in synthesis example 5 except that 4-(9H-carbazol-9-yl) phenylboronic acid was replaced by 4-(9,9-dimethyl-9,10-dihydroacridin-10-yl) phenylboronic acid and 12H-4,8-dioxa-3a²-boroxadibenzo[cd,mn] pyrene-12-one was replaced by 4H-3a²-boroxadibenzo[cd,mn] pyrene-4,8,12-one. ¹H NMR (500 MHz, Chloroform-D) δ 8.42 (s, 1H), 8.14 (s, 1H), 7.93 (m, 3H), 7.78 (t, J=10.0 Hz, 4H), 7.64 (m, 3H), 7.55 (s, 2H), 7.48 (s, 2H), 7.37 (s, 2H), 7.20 (m, 8H), 6.94 (s, 2H), 1.69 (s, 6H).

### Synthesis Example 8: Synthesis of Compound 25

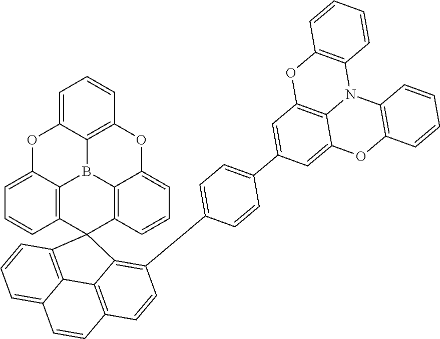 [SMILES: c1ccc2c(c1)Oc1cc(-c3ccc(-c4ccc5ccc6cccc7c6c5c4C74c5cccc6c5B5c7c(cccc7Oc7cccc4c75)O6)cc3)cc3c1N2c1ccccc1O3]

Compound 25 was synthesized in the same method as that in synthesis example 5 except that 4-(9H-carbazol-9-yl) phenylboronic acid was replaced by 4-(benzo[5,6][1,4]oxazine[2,3,4-kl]phenoxazin-7-yl) phenylboronic acid. ¹H NMR (500 MHz, Chloroform-D) δ 8.42 (s, 1H), 8.14 (s, 1H), 7.92 (s, 2H), 7.80 (s, 1H), 7.62 (s, 1H), 7.31 (s, 1H), 7.25 (s, 4H), 7.15 (m, 4H), 7.07-6.82 (m, 12H), 6.69 (s, 2H), 5.53 (s, 1H).

### Synthesis Example 9: Synthesis of Compound 36

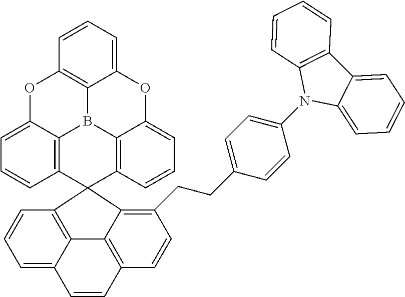 [SMILES: c1cc2c3c(c1)Oc1cccc4c1B3c1c(cccc1C41c3cccc4ccc5ccc(CCc6ccc(-n7c8ccccc8c8ccccc87)cc6)c1c5c34)O2]

Compound 36 was synthesized in the same method as that in synthesis example 5 except that 4-(9H-carbazol-9-yl) phenylboronic acid was replaced by 2-[4-(carbazol-9-yl)phenyl]ethylboronic acid. ¹H NMR (500 MHz, Chloroform-D) δ 8.53 (s, 1H), 8.20 (m, 2H), 7.99 (s, 1H), 7.90 (s, 2H), 7.78 (s, 1H), 7.65 (m, 2H), 7.49 (m, 3H), 7.38 (s, 1H), 7.28 (d, J=10.0 Hz, 3H), 7.21-7.04 (m, 6H), 6.94 (s, 2H), 6.85 (s, 2H), 6.67 (s, 2H), 2.92 (s, 2H), 2.81 (s, 2H).

### In an Exemplary Device Example:

Evaporation device was prepared using DPEPO as a host material of luminescent layer (HOST) and using compounds 1, 2, 6, 7, 9, 10, 18, 25, 36 of the synthesis examples and a comparative compound (Ref.) as guest material of the luminescent layer, respectively. The weight percentage of the guest material in the luminescent layer was 10 wt % based on the total weight of the luminescent layer.

The structure of the evaporation device was as follows:

ITO/HAT-CN (6 nm)/NPB (30 nm)/TCTA (10 nm)/mCP (10 nm)/compound (10 wt %):HOST (20 nm)/DPEPO (5 nm)/TmPyPB (40 nm)/LiF (1.5 nm)/Ag:Mg (100 nm, doping ratio of 10:1).

Among them, ITO thin layer on glass substrate was used as anode, HAT-CN was used as hole injection layer, NPB and TCTA was used as hole transport layer, mCP was used as electron barrier layer, DPEPO was used as hole barrier layer, TmPyPB was used as electron transport layer/LiF was used as electron injection layer, and Ag:Mg was used as cathode.

The structure of the corresponding material was as follows:

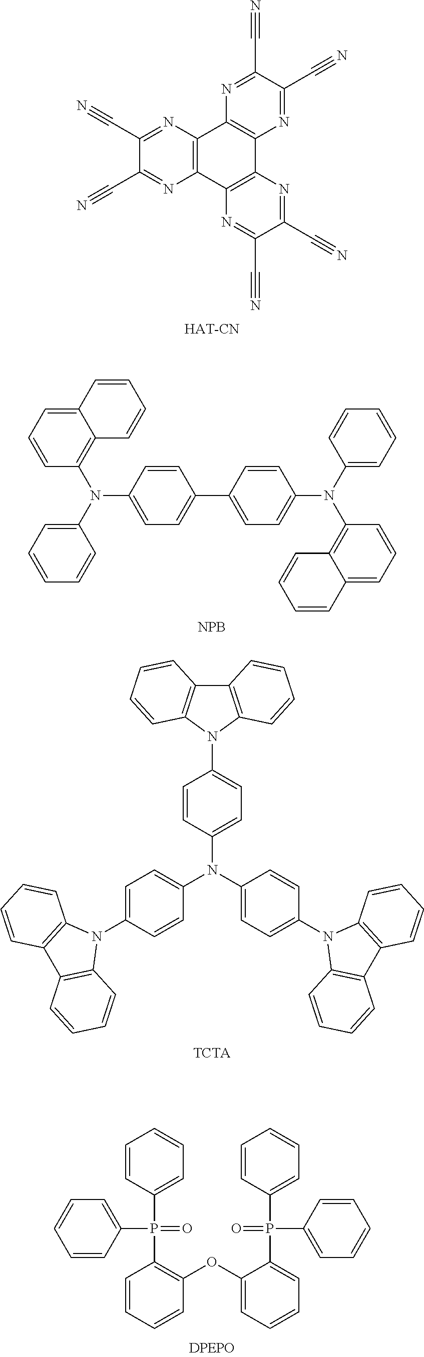

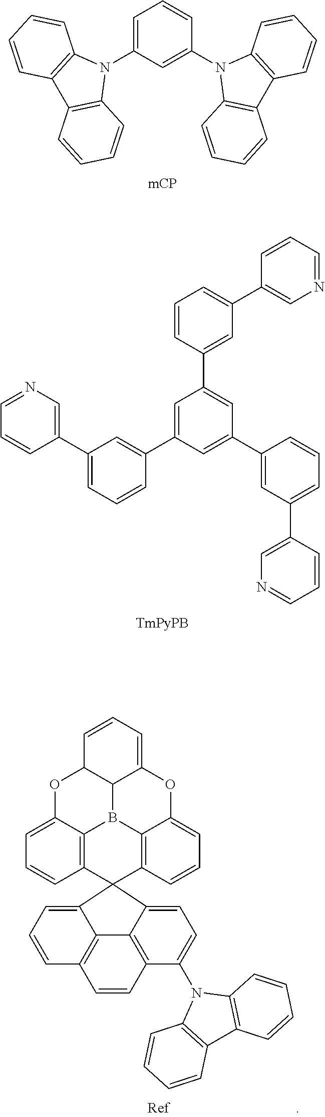 [SMILES: c1cc(-n2c3ccccc3c3ccccc32)cc(-n2c3ccccc3c3ccccc32)c1 ; c1cncc(-c2cccc(-c3cc(-c4cccc(-c5cccnc5)c4)cc(-c4cccc(-c5cccnc5)c4)c3)c2)c1 ; C1=CC2Oc3cccc4c3B3c5c(cccc5C45c4cccc6ccc7c(-n8c9ccccc9c9ccccc98)ccc5c7c46)OC(=C1)C32]

Some properties of the prepared electroluminescent device are shown in Table 1:

TABLE 1

| | | | | External | |
|---|---|---|---|---|---|
| | Compound | Turn-on | | quantum | Life |
| Device | (luminescent | voltage | Brightness | efficiency | (LT95@1000 |
| No. | guest) | (V) | (Cd/m²) | (%) | nit) |
| 1-1 | Ref. | 100% | 100% | 100% | 100% |
| 1-2 | 1 | 95% | 121% | 106% | 107% |
| 1-3 | 2 | 96% | 125% | 108% | 108% |
| 1-4 | 6 | 96% | 110% | 105% | 106% |
| 1-5 | 7 | 95% | 112% | 107% | 101% |
| 1-6 | 9 | 96% | 108% | 106% | 103% |
| 1-7 | 10 | 96% | 113% | 111% | 110% |
| 1-8 | 18 | 97% | 117% | 112% | 108% |
| 1-9 | 25 | 99% | 115% | 110% | 113% |
| 1-10 | 36 | 98% | 105% | 105% | 107% |

It can be seen from Table 1 that the compound of the present disclosure is a blue TADF excimer composite material with good device performance, and OLED devices using it as the guest material of the luminescent layer all exhibit electroluminescent performances with high efficiency, low driving voltage and long life.

### In an Exemplary Device Example:

Evaporation devices were prepared using the compounds of the present disclosure and the comparative compound (Ref.) as sensitizing material of the luminescent layer.

The luminescent layer was formed by using 4,4′-bis(9H-carbazol-9-yl)-1,1′-biphenyl (CBP, chemical formula as follows) as the main material of the luminescent layer, DCJTB (chemical formula as follows) as the luminescent dye, compounds 1, 2, 6, 7, 9, 10, 18, 25, 36 and comparative compound (Ref.) as sensitizers, respectively, and performing vacuum evaporation with CBP, compounds, and DCJTB at a mass ratio of 79:20:1, and co-depositing on the exciton/electron barrier layer, with a thickness of the deposited thin film of 20 nm.

The structure of the evaporation device was as follows:

ITO/HAT-CN (6 nm)/NPB (30 nm)/TCTA (10 nm)/mCP (10 nm)/CBP: Compound: DCJTB/DPEPO (5 nm)/TmPyPB (40 nm)/LiF (1.5 nm)/Ag:Mg (100 nm, doping ratio of 10:1).

Among them, ITO thin layer on glass substrate was used as anode, HAT-CN was used as hole injection layer, NPB and TCTA were used as hole transport layer, mCP was used as electron barrier layer, DPEPO was used as hole barrier layer, TmPyPB was used as electron transport layer/LiF was used as electron injection layer, and Ag:Mg was used as cathode.

The structure of CBP and DCJTB was as follows:

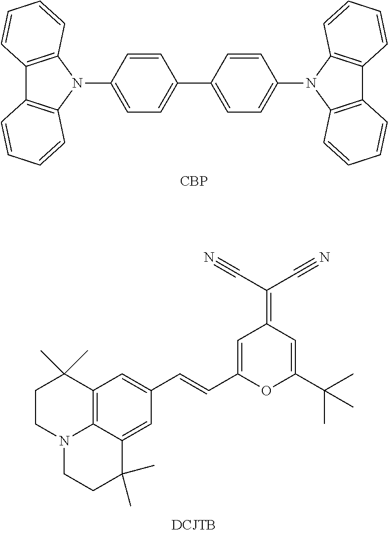 [SMILES: c1ccc2c(c1)c1ccccc1n2-c1ccc(-c2ccc(-n3c4ccccc4c4ccccc43)cc2)cc1 ; "CBP" ; CC(C)(C)C1=CC(=C(C#N)C#N)C=C(/C=C/c2cc3c4c(c2)C(C)(C)CCN4CCC3(C)C)O1]

Some properties of the prepared electroluminescent devices are shown in Table 2:

TABLE 2

| | | | | External | |
|---|---|---|---|---|---|
| | Compound | Turn-on | | quantum | Life |
| Device | (Sensitizing | voltage | Brightness | efficiency | (LT95@1000 |
| No. | material) | (V) | (Cd/m²) | (%) | nit) |
| 2-1 | Ref | 100% | 100% | 100% | 100% |
| 2-2 | 1 | 94% | 115% | 125% | 117% |
| 2-3 | 2 | 96% | 108% | 118% | 109% |
| 2-4 | 6 | 95% | 111% | 120% | 111% |
| 2-5 | 7 | 96% | 110% | 120% | 110% |
| 2-6 | 9 | 99% | 102% | 110% | 103% |
| 2-7 | 10 | 96% | 115% | 114% | 112% |
| 2-8 | 18 | 95% | 119% | 115% | 110% |
| 2-9 | 25 | 97% | 117% | 113% | 115% |
| 2-10 | 36 | 96% | 107% | 108% | 109% |

It can be seen from Table 2 that the compound of the present disclosure is a TADF material with good device performance, and OLED devices using it as the sensitizing material of the luminescent layer all exhibit electroluminescent performances with high efficiency, low driving voltage and long life.

Although the present disclosure has been described as above the contents described are for the sake of ease of understanding of the embodiments employed in the present disclosure only and are not intended to limit the present disclosure. Any person skilled in the art of the present disclosure may make any modification and change in forms and details of implementation without departing from the spirit and scope disclosed in the present disclosure. However, the scope of patent protection of the present disclosure is still subject to the scope defined in the appended claims.

1. A compound of Formula 1: 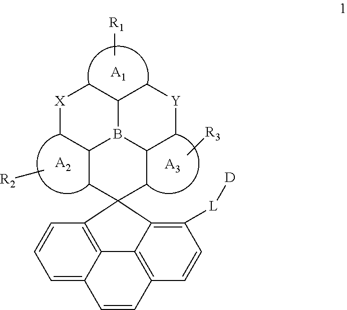
wherein:
X and Y are each independently selected from one of O, S, Se, C═O, S(═O)₂, CR₄R₅, SiR₄R₅, NR₄, PR₄, P(═O)R₄, and BR₄;
A₁ to A₃ are each independently selected from substituted or unsubstituted C6-C18 aromatic ring, substituted or unsubstituted 5-18 membered heteroaromatic ring;
R₁ to R3 each independently represent 1 or more substituents each independently selected from hydrogen, deuterium, halogen atom, cyano, nitro, hydroxy, substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C6-C18 aryl, substituted or unsubstituted 5-18 membered heteroaryl, substituted or unsubstituted 5-18 membered heterocyclyl, or are bonded with an adjacent group to form a 5-18 membered ring;
R₄ to R₅ are each independently selected from substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C6-C18 aryl, substituted or unsubstituted 5-18 membered heteroaryl, substituted or unsubstituted 5-18 membered heterocyclyl, or is bonded with an adjacent group to form a 5-18 membered ring;
L is a linking group selected from a direct linking bond, an oxygen atom, substituted or unsubstituted C1-C6 alkylene, substituted or unsubstituted C1-C6 alkoxylene, substituted or unsubstituted C6-C18 arylene, substituted or unsubstituted C6-C18 aryloxylene, substituted or unsubstituted C1-C6 alkylene C6-C18 arylene, substituted or unsubstituted 5-18 membered heteroarylene, substituted or unsubstituted 5-18 membered heteroaryloxylene, substituted or unsubstituted C1-C6 alkylene 5-18 membered heteroarylene; and
D is an electron-rich heterocyclyl group with hole transport ability.

2. The compound according to claim 1, wherein, D is selected from: carbazole and its derivatives, fused carbazole and its derivatives, diphenylamine and its derivatives, aromatic heterocyclyl substituted diarylamine derivatives, acridine and its derivatives, phenoxazine and its derivatives, phenothiazine and its derivatives.

3. The compound according to claim 2, wherein, D is selected from the following groups: 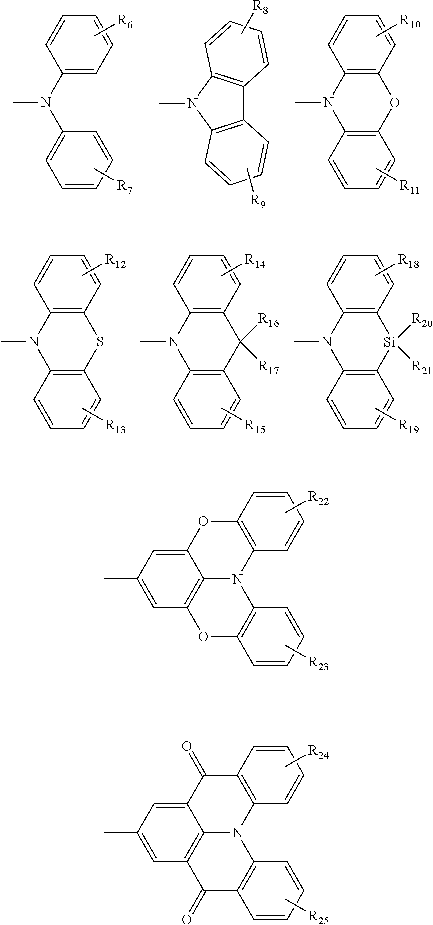
wherein, R₆ to R₁₅, R₁₈ to R₁₉, and R₂₂ to R₂₅ each independently represent 1 or more substituents each independently selected from hydrogen, substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C1-C18 alkylsulfanyl, substituted or unsubstituted amine group, substituted or unsubstituted C6-C30 arylsulfanyl, substituted or unsubstituted C6-C30 aryloxy, substituted or unsubstituted C6-C30 aryl, substituted or unsubstituted 5-30 membered heteroaryl, or can be bonded with an adjacent group to form a 5-30 membered ring, and
R₁₆ to R₁₇, and R₂₀ to R₂₁ are independently selected from hydrogen, substituted or unsubstituted C1-C18 alkyl, substituted or unsubstituted C2-C18 alkenyl, substituted or unsubstituted C2-C18 alkynyl, substituted or unsubstituted C3-C18 cycloalkyl, substituted or unsubstituted C1-C18 alkoxy, substituted or unsubstituted C1-C18 alkylsulfanyl, substituted or unsubstituted C6-C30 arylsulfanyl, substituted or unsubstituted C6-C30 aryloxy, substituted or unsubstituted amine group, substituted or unsubstituted C6-C30 aryl, substituted or unsubstituted 5-30 membered heteroaryl, substituted or unsubstituted 5-30 membered heterocyclyl, or are bonded with an adjacent group to form a 5-30 membered ring.

4. The compound according to claim 3, wherein:
R₆ to R₁₅, R₁₈ to R₁₉, and R₂₂ to R₂₅ each independently represent 1 or 2 substituents each independently selected from hydrogen, substituted or unsubstituted C1-C6 alkyl, or are bonded with an adjacent group to form a 5-20 membered ring; and
R₁₆ to R₁₇, and R₂₀ to R₂₁ are each independently selected from hydrogen, substituted or unsubstituted C1-C4 alkyl, substituted or unsubstituted C6-C10 aryl, or are bonded with an adjacent group to form a 5-20 membered ring.

5. The compound according to claim 3, wherein, D is selected from the following groups:

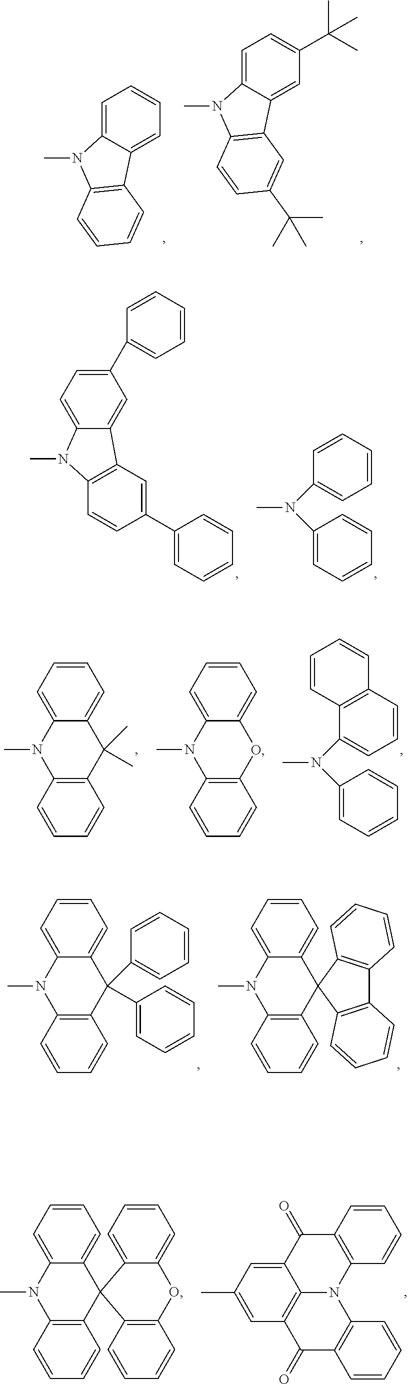

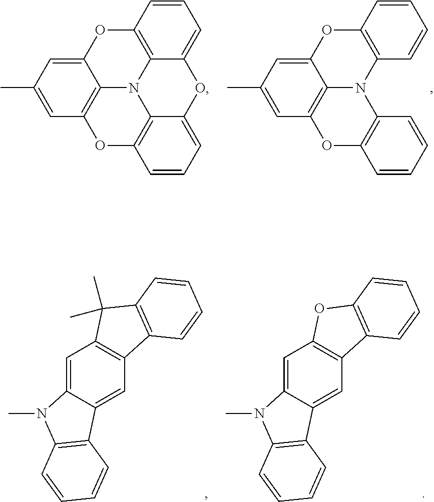

6. The compound according to claim 1, wherein:
L is selected from a direct linking bond, an oxygen atom, substituted or unsubstituted C1-C4 alkylene, substituted or unsubstituted C1-C4 alkoxylene, substituted or unsubstituted C6-C12 arylene, substituted or unsubstituted C6-C12 aryloxylene, substituted or unsubstituted C1-C4 alkylene C6-C12 arylene, substituted or unsubstituted 5-12 membered heteroarylene, substituted or unsubstituted 5-12 membered heteroaryloxylene, substituted or unsubstituted C1-C4 alkylene 5-12 membered heteroarylene.

7. The compound according to claim 6, wherein:
L is selected from a direct linking bond, an oxygen atom, phenylene, pyridylene, furylene, C1-C4 alkylene, C1-C4 alkylene phenylene, phenoxylene.

8. The compound according to claim 1, wherein:
X and Y are each independently selected from any one of O, S, Se, C═O, S(═O)₂, CR₄R₅, and BR₄;
A₁ to A₃ are benzene rings;
R₁ to R₃ each independently represent 1 to 2 substituents each independently selected from hydrogen, deuterium, cyano;
R₄ to R₅ are each independently selected from hydrogen, deuterium, substituted or unsubstituted C1-C6 alkyl, substituted or unsubstituted C6-C10 aryl.

9. The compound according to claim 1, wherein, the compound is selected from the following compounds: 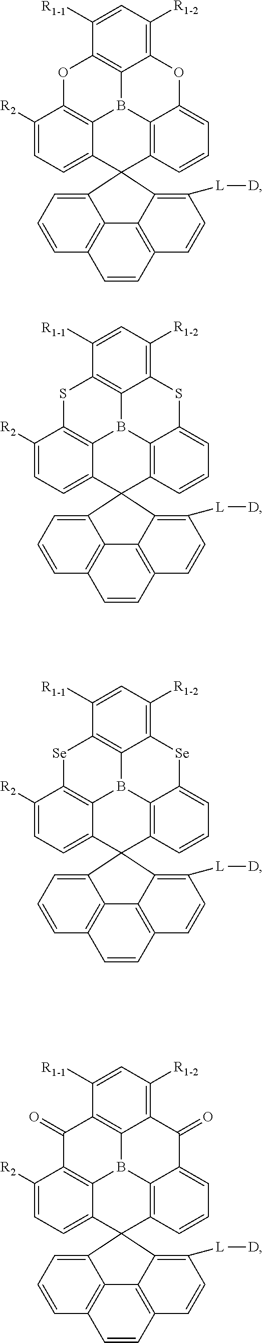 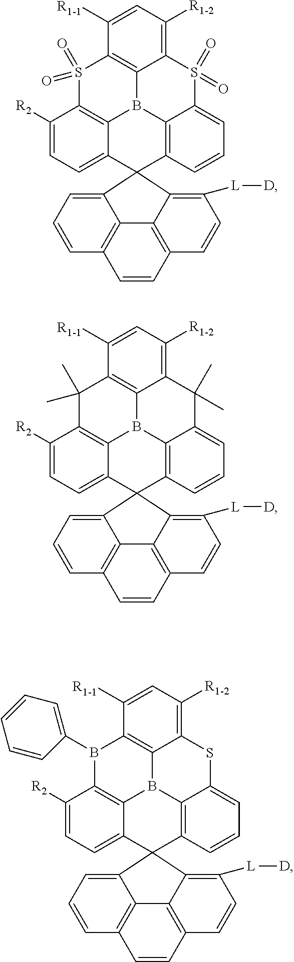
wherein:
R₁₋₁, R₁₋₂ and R₂ are each independently selected from hydrogen, cyano; and
L and D are defined in the same way as in the claims cited.

10. The compound according to claim 1, wherein, the compound is selected from the following compounds:

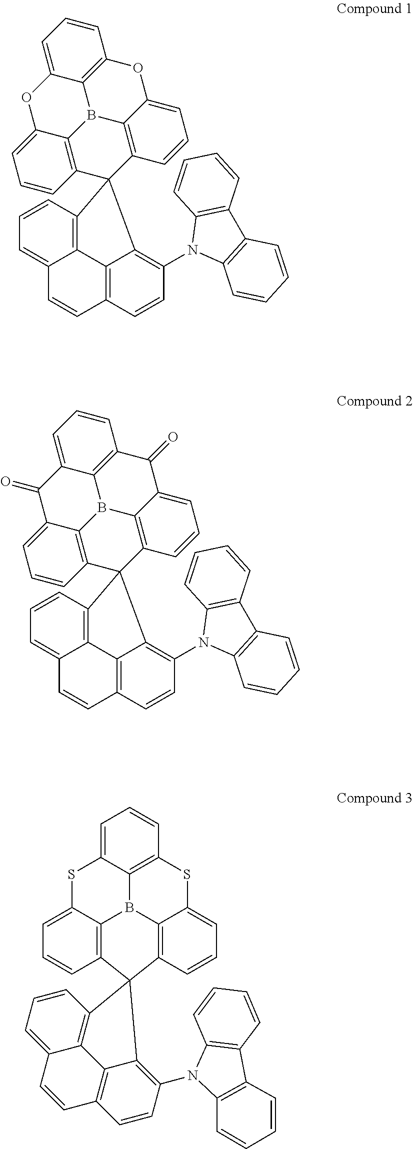 [SMILES: c1cc2c3c(c1)Oc1cccc4c1B3c1c(cccc1C41c3cccc4ccc5ccc(-n6c7ccccc7c7ccccc76)c1c5c34)O2 ; O=C1c2cccc3c2B2c4c1cccc4C1(c4cccc(c42)C3=O)c2cccc3ccc4ccc(-n5c6ccccc6c6ccccc65)c1c4c23 ; c1cc2c3c(c1)Sc1cccc4c1B3c1c(cccc1C41c3cccc4ccc5ccc(-n6c7ccccc7c7ccccc76)c1c5c34)S2]

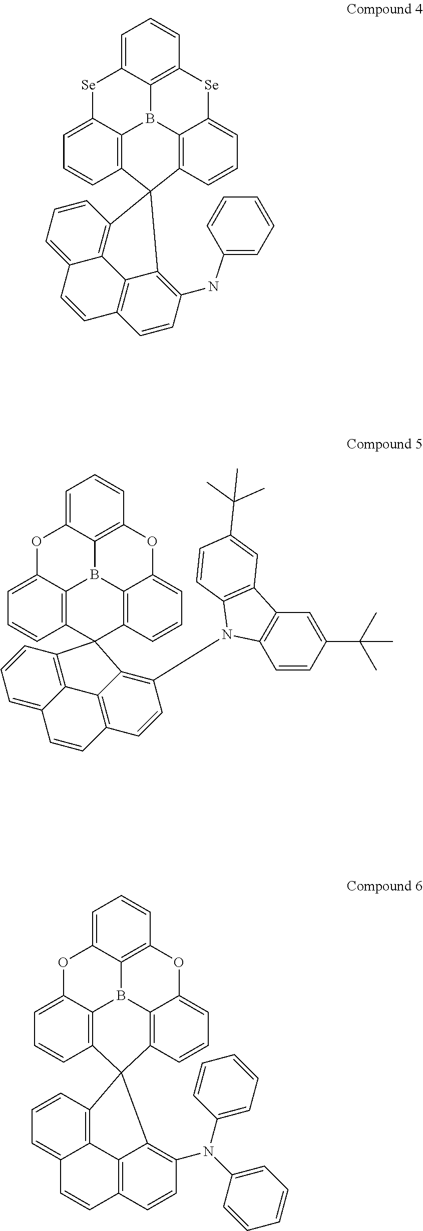 [SMILES: c1ccc(Nc2ccc3ccc4cccc5c4c3c2C52c3cccc4c3B3c5c(cccc5[Se]c5cccc2c53)[Se]4)cc1 ; CC(C)(C)c1ccc2c(c1)c1cc(C(C)(C)C)ccc1n2-c1ccc2ccc3cccc4c3c2c1C41c2cccc3c2B2c4c(cccc4Oc4cccc1c42)O3 ; c1ccc(N(c2ccccc2)c2ccc3ccc4cccc5c4c3c2C52c3cccc4c3B3c5c(cccc5Oc5cccc2c53)O4)cc1]

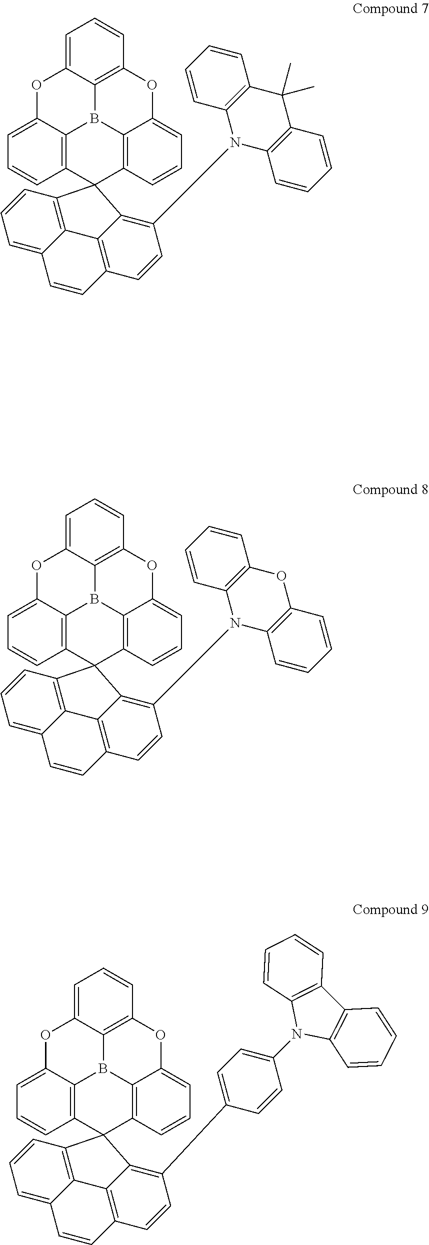 [SMILES: CC1(C)c2ccccc2N(c2ccc3ccc4cccc5c4c3c2C52c3cccc4c3B3c5c(cccc5Oc5cccc2c53)O4)c2ccccc21 ; c1ccc2c(c1)Oc1ccccc1N2c1ccc2ccc3cccc4c3c2c1C41c2cccc3c2B2c4c(cccc4Oc4cccc1c42)O3 ; c1cc2c3c(c1)Oc1cccc4c1B3c1c(cccc1C41c3cccc4ccc5ccc(-c6ccc(-n7c8ccccc8c8ccccc87)cc6)c1c5c34)O2]

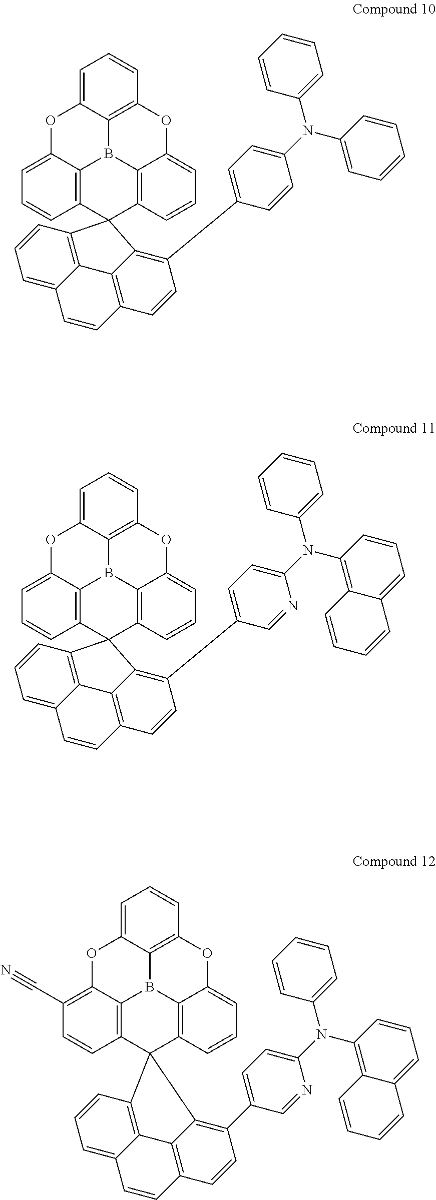 [SMILES: c1ccc(N(c2ccccc2)c2ccc(-c3ccc4ccc5cccc6c5c4c3C63c4cccc5c4B4c6c(cccc6Oc6cccc3c64)O5)cc2)cc1 ; c1ccc(N(c2ccc(-c3ccc4ccc5cccc6c5c4c3C63c4cccc5c4B4c6c(cccc6Oc6cccc3c64)O5)cn2)c2cccc3ccccc23)cc1 ; N#Cc1ccc2c3c1Oc1cccc4c1B3c1c(cccc1C21c2cccc3ccc5ccc(-c6ccc(N(c7ccccc7)c7cccc8ccccc78)nc6)c1c5c23)O4]

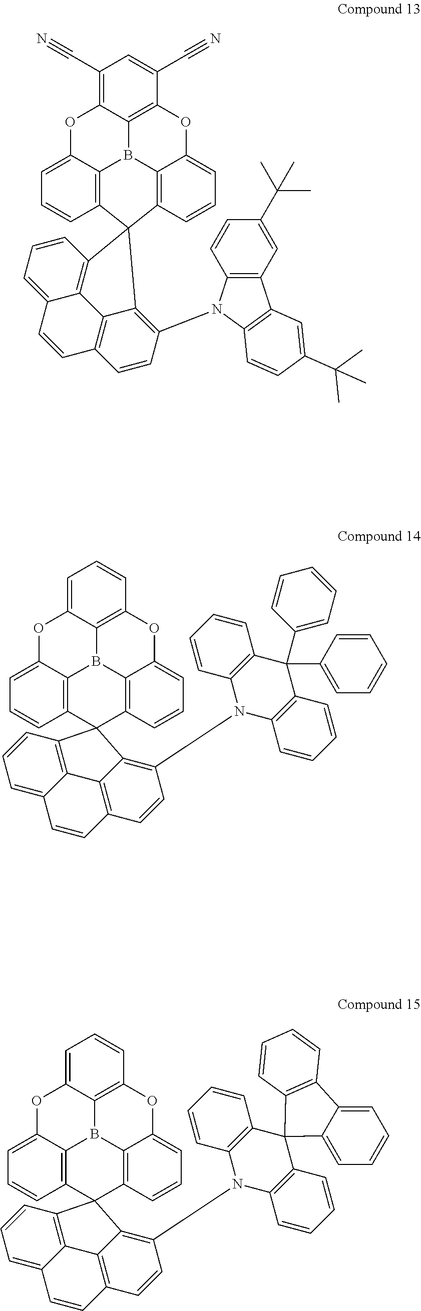 [SMILES: CC(C)(C)c1ccc2c(c1)c1cc(C(C)(C)C)ccc1n2-c1ccc2ccc3cccc4c3c2c1C41c2cccc3c2B2c4c(cccc41)Oc1c(C#N)cc(C#N)c(c12)O3 ; c1ccc(C2(c3ccccc3)c3ccccc3N(c3ccc4ccc5cccc6c5c4c3C63c4cccc5c4B4c6c(cccc6Oc6cccc3c64)O5)c3ccccc32)cc1 ; c1cc2c3c(c1)Oc1cccc4c1B3c1c(cccc1C41c3cccc4ccc5ccc(N6c7ccccc7C7(c8ccccc8-c8ccccc87)c7ccccc76)c1c5c34)O2]

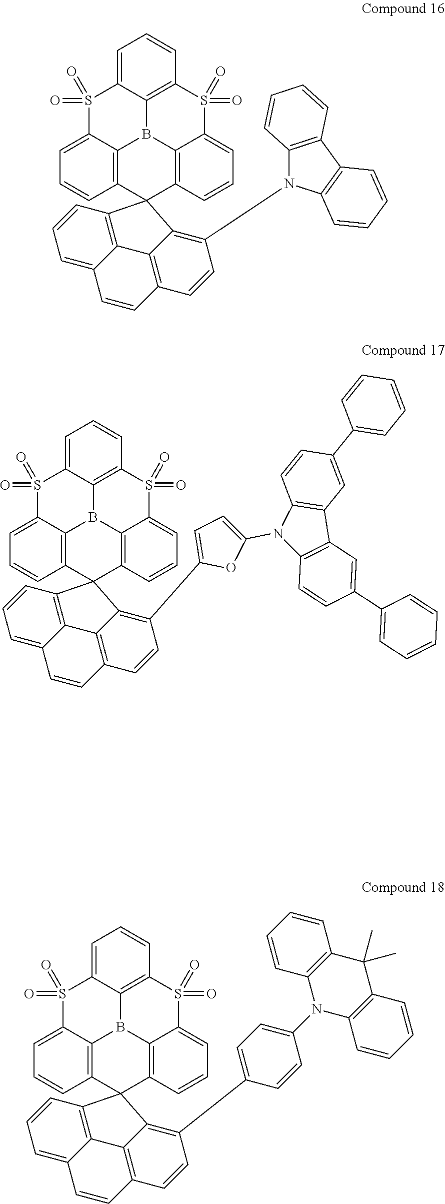 [SMILES: O=S1(=O)c2cccc3c2B2c4c(cccc4S(=O)(=O)c4cccc1c42)C31c2cccc3ccc4ccc(-n5c6ccccc6c6ccccc65)c1c4c23 ; O=S1(=O)c2cccc3c2B2c4c(cccc4S(=O)(=O)c4cccc1c42)C31c2cccc3ccc4ccc(-c5ccc(-n6c7ccc(-c8ccccc8)cc7c7cc(-c8ccccc8)ccc76)o5)c1c4c23 ; CC1(C)c2ccccc2N(c2ccc(-c3ccc4ccc5cccc6c5c4c3C63c4cccc5c4B4c6c3cccc6S(=O)(=O)c3cccc(c34)S5(=O)=O)cc2)c2ccccc21]

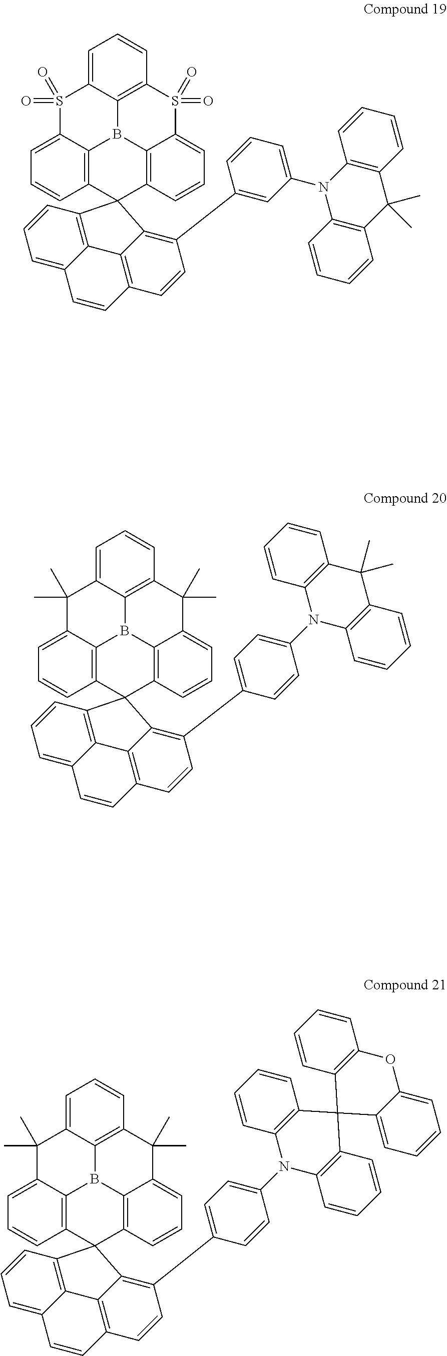 [SMILES: CC1(C)c2ccccc2N(c2cccc(-c3ccc4ccc5cccc6c5c4c3C63c4cccc5c4B4c6c3cccc6S(=O)(=O)c3cccc(c34)S5(=O)=O)c2)c2ccccc21 ; CC1(C)c2ccccc2N(c2ccc(-c3ccc4ccc5cccc6c5c4c3C63c4cccc5c4B4c6c(cccc6C(C)(C)c6cccc3c64)C5(C)C)cc2)c2ccccc21 ; CC1(C)c2cccc3c2B2c4c1cccc4C1(c4cccc(c42)C3(C)C)c2cccc3ccc4ccc(-c5ccc(N6c7ccccc7C7(c8ccccc8Oc8ccccc87)c7ccccc76)cc5)c1c4c23]

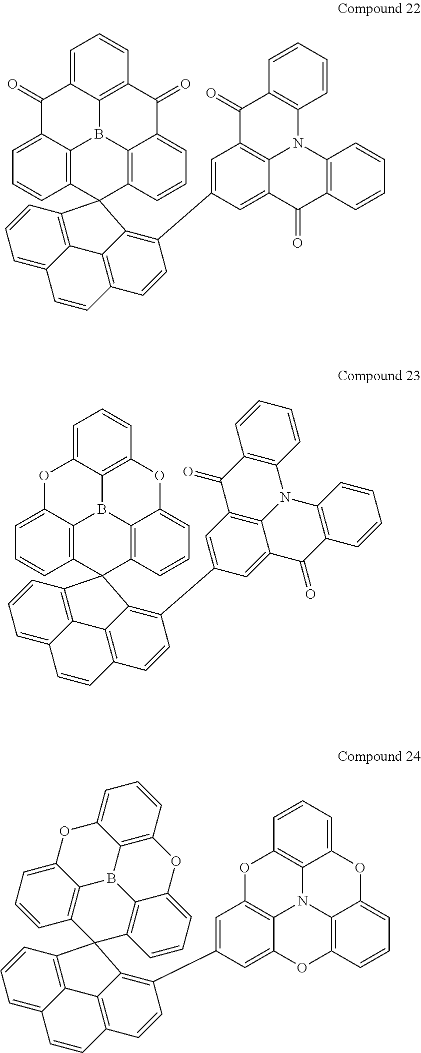 [SMILES: O=C1c2cccc3c2B2c4c1cccc4C1(c4cccc(c42)C3=O)c2cccc3ccc4ccc(-c5cc6c(=O)c7ccccc7n7c8ccccc8c(=O)c(c5)c67)c1c4c23 ; O=c1c2ccccc2n2c3ccccc3c(=O)c3cc(-c4ccc5ccc6cccc7c6c5c4C74c5cccc6c5B5c7c(cccc7Oc7cccc4c75)O6)cc1c32 ; c1cc2c3c(c1)Oc1cccc4c1B3c1c(cccc1C41c3cccc4ccc5ccc(-c6cc7c8c(c6)Oc6cccc9c6N8c6c(cccc6O7)O9)c1c5c34)O2]

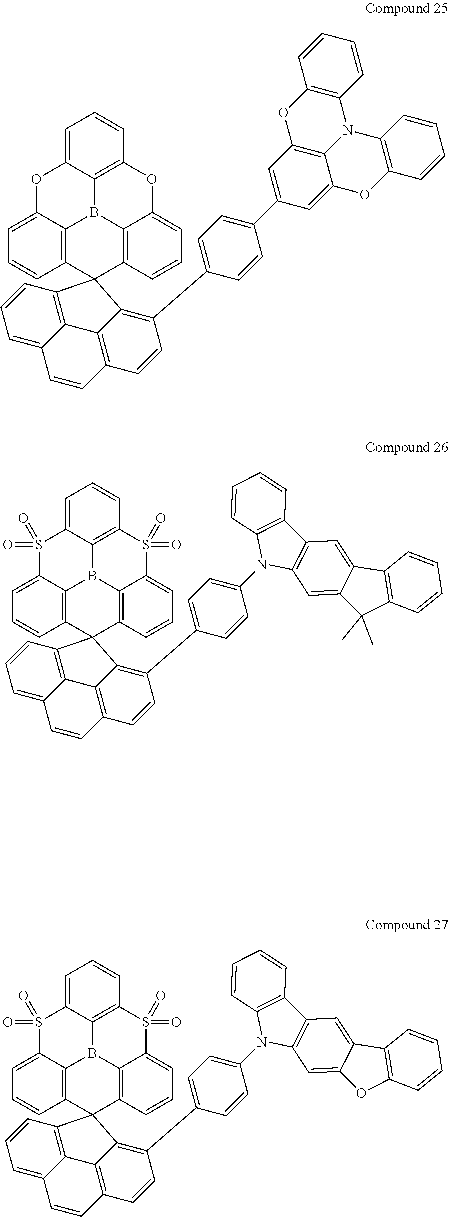 [SMILES: c1ccc2c(c1)Oc1cc(-c3ccc(-c4ccc5ccc6cccc7c6c5c4C74c5cccc6c5B5c7c(cccc7Oc7cccc4c75)O6)cc3)cc3c1N2c1ccccc1O3 ; CC1(C)c2ccccc2-c2cc3c4ccccc4n(-c4ccc(-c5ccc6ccc7cccc8c7c6c5C85c6cccc7c6B6c8c5cccc8S(=O)(=O)c5cccc(c56)S7(=O)=O)cc4)c3cc21 ; O=S1(=O)c2cccc3c2B2c4c(cccc4S(=O)(=O)c4cccc1c42)C31c2cccc3ccc4ccc(-c5ccc(-n6c7ccccc7c7cc8c(cc76)oc6ccccc68)cc5)c1c4c23]

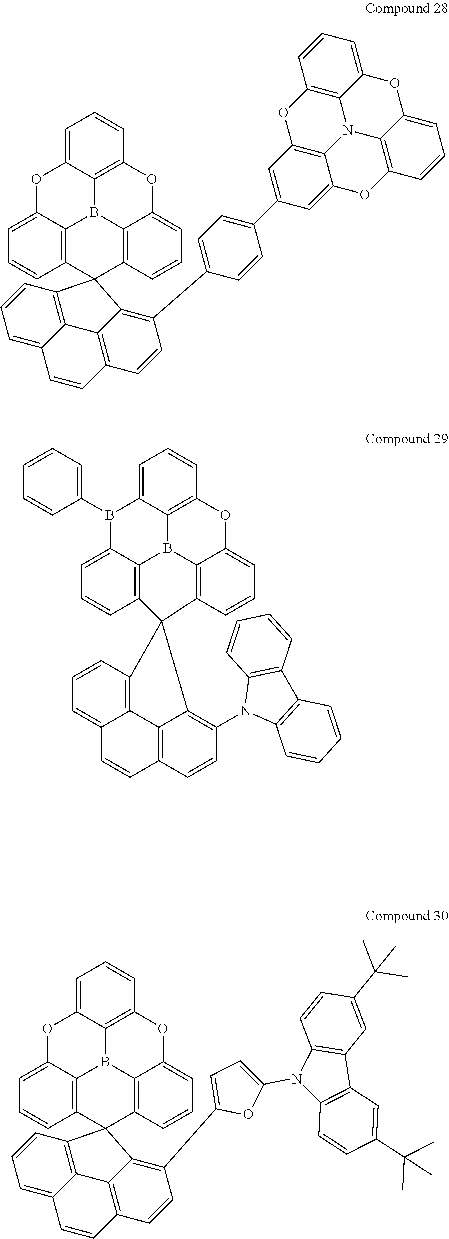 [SMILES: c1cc2c3c(c1)Oc1cccc4c1B3c1c(cccc1C41c3cccc4ccc5ccc(-c6ccc(-c7cc8c9c(c7)Oc7cccc%10c7N9c7c(cccc7O8)O%10)cc6)c1c5c34)O2 ; c1ccc(B2c3cccc4c3B3c5c(cccc5C5(c6cccc2c63)c2cccc3ccc6ccc(-n7c8ccccc8c8ccccc87)c5c6c23)O4)cc1 ; CC(C)(C)c1ccc2c(c1)c1cc(C(C)(C)C)ccc1n2-c1ccc(-c2ccc3ccc4cccc5c4c3c2C52c3cccc4c3B3c5c(cccc5Oc5cccc2c53)O4)o1]

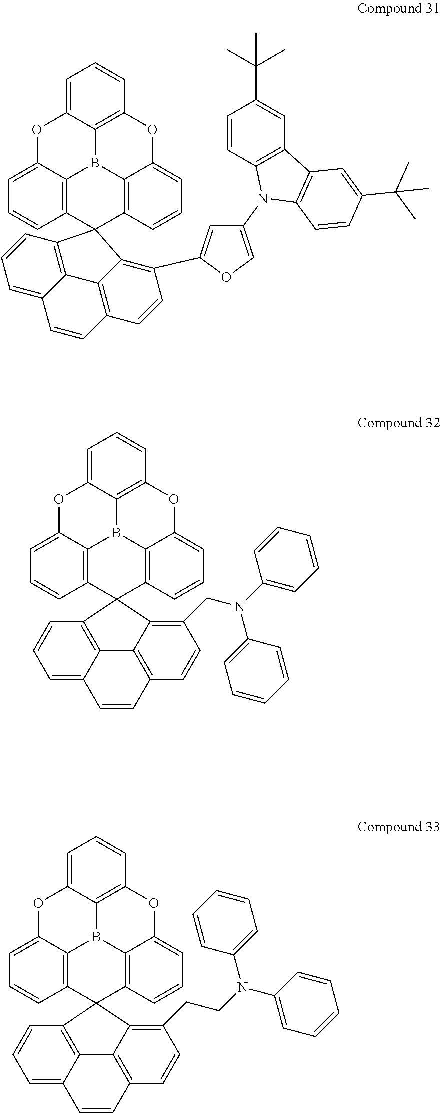 [SMILES: CC(C)(C)c1ccc2c(c1)c1cc(C(C)(C)C)ccc1n2-c1coc(-c2ccc3ccc4cccc5c4c3c2C52c3cccc4c3B3c5c(cccc5Oc5cccc2c53)O4)c1 ; c1ccc(N(Cc2ccc3ccc4cccc5c4c3c2C52c3cccc4c3B3c5c(cccc5Oc5cccc2c53)O4)c2ccccc2)cc1 ; c1ccc(N(CCc2ccc3ccc4cccc5c4c3c2C52c3cccc4c3B3c5c(cccc5Oc5cccc2c53)O4)c2ccccc2)cc1]

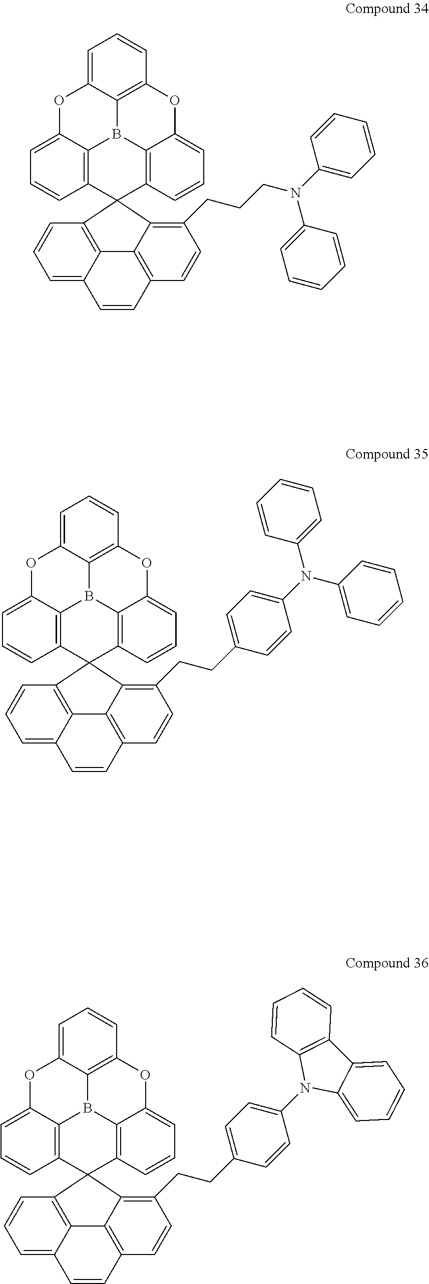 [SMILES: c1ccc(N(CCCc2ccc3ccc4cccc5c4c3c2C52c3cccc4c3B3c5c(cccc5Oc5cccc2c53)O4)c2ccccc2)cc1 ; c1ccc(N(c2ccccc2)c2ccc(CCc3ccc4ccc5cccc6c5c4c3C63c4cccc5c4B4c6c(cccc6Oc6cccc3c64)O5)cc2)cc1 ; c1cc2c3c(c1)Oc1cccc4c1B3c1c(cccc1C41c3cccc4ccc5ccc(CCc6ccc(-n7c8ccccc8c8ccccc87)cc6)c1c5c34)O2]

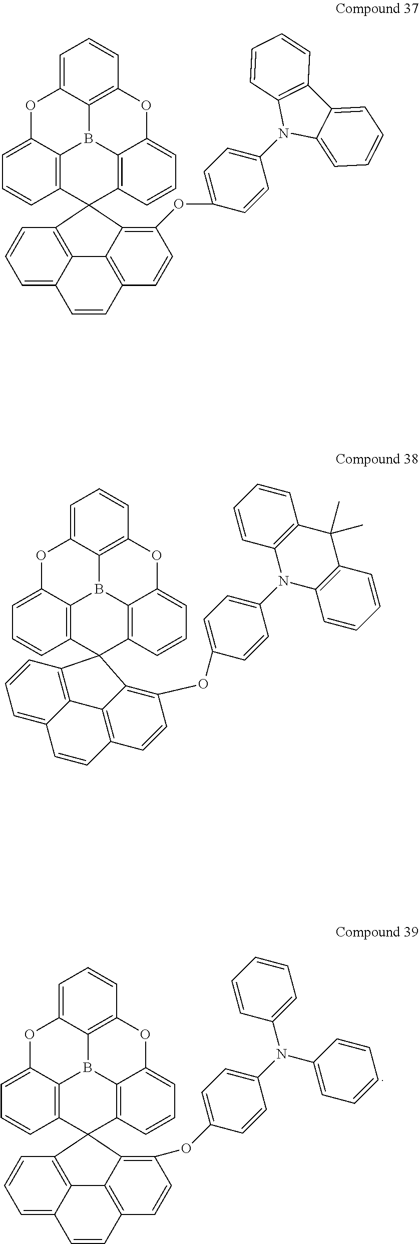 [SMILES: c1cc2c3c(c1)Oc1cccc4c1B3c1c(cccc1C41c3cccc4ccc5ccc(Oc6ccc(-n7c8ccccc8c8ccccc87)cc6)c1c5c34)O2 ; CC1(C)c2ccccc2N(c2ccc(Oc3ccc4ccc5cccc6c5c4c3C63c4cccc5c4B4c6c(cccc6Oc6cccc3c64)O5)cc2)c2ccccc21 ; c1ccc(N(c2ccccc2)c2ccc(Oc3ccc4ccc5cccc6c5c4c3C63c4cccc5c4B4c6c(cccc6Oc6cccc3c64)O5)cc2)cc1]

11. A synthesis method of a compound of Formula 1 according to claim 1, wherein, the synthesis method is represented by the following reaction equation 1, and comprises: 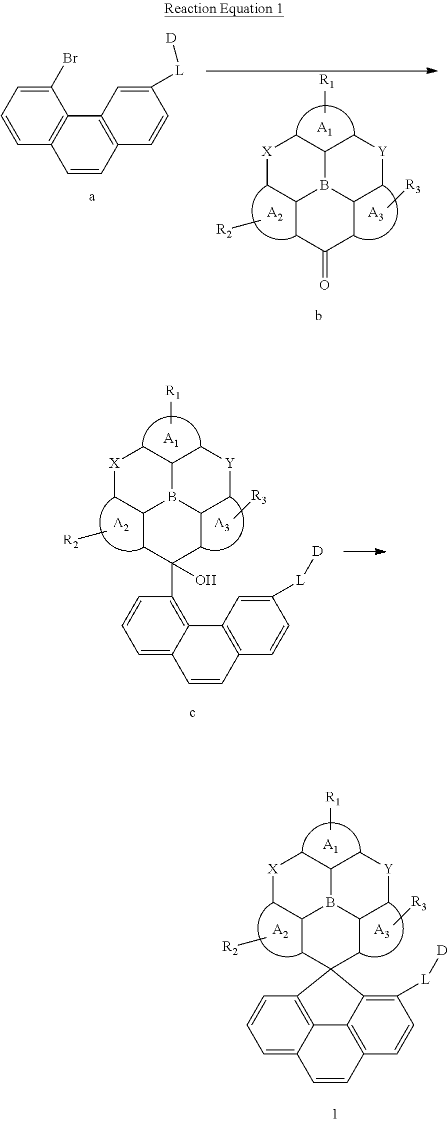
(1) reacting compound a with compound b to obtain compound c; and
(2) reacting the compound c to obtain a compound of Formula 1;
wherein, each substituent is defined in the same way as in the claims cited.

12. Use of the compound according to claim 1 for the preparation of an organic luminescent material.

13. The use according to claim 12, wherein, the organic luminescent material is a TADF type organic luminescent material.

14. The use according to claim 12, wherein, the organic luminescent material is a guest material or a sensitizing material of a luminescent layer.

15. Use of the compound according to claim 1 for the preparation of an organic electroluminescent device.

16. An organic electroluminescent device comprising a luminescent layer, wherein, the luminescent layer comprises a compound according to claim 1.

17. A display device, comprising the organic electroluminescent device according to claim 16.

18. The compound according to claim 1, wherein, R₁ to R3 each independently represent 1, 2, or 3 substituents.

19. The compound according to claim 3, wherein, R₆ to R₁₅, R₁₈ to R₁₉, and R₂₂ to R₂₅ each independently represent 1, 2, or 3 substituents.
